(19) United States
(12) Patent Application Publication
(10) Pub. No.: US 2026/0147972 A1
(43) Pub. Date: May 28, 2026

(54) SYSTEMS AND METHODS FOR IMPROVING PERFORMANCE OF ELECTRONIC CIRCUITS

(71) Applicant: Astrus Inc., Toronto (CA)

(72) Inventors: Bradley James Moon, Toronto (CA); Zeyi Wang, Toronto (CA); Kenneth John Young, Toronto (CA)

(21) Appl. No.: 19/394,430

(22) Filed: Nov. 19, 2025

Related U.S. Application Data
(60) Provisional application No. 63/726,141, filed on Nov. 27, 2024.
(60) Provisional application No. 63/858,177, filed on Aug. 5, 2025.

(51) Int. Cl. G06F 30/392; G06F 30/398; G06N 3/092

(52) U.S. Cl. CPC G06F 30/392; G06F 30/398; G06N 3/092

(57) ABSTRACT

Disclosed herein are systems and methods for generating layouts of circuits to optimize for a performance of a circuit by, for example, mitigating parasitic capacitance or parasitic resistance. Herein is a method of designing a layout of an electronic circuit, the method comprising: receiving a circuit schematic of an electronic circuit and one or more target of the electronic circuit, wherein the circuit schematic comprises at least a plurality of circuit components; and designing the layout of the electronic circuit based at least in part on the plurality of components and the one or more target via a series of operations executed by an artificial intelligence (AI) agent.

### CROSS-REFERENCE

This application claims the benefit of U.S. Provisional Application No. 63/726,141, filed Nov. 27, 2024, and U.S. Provisional Application No. 63/858,177, filed Aug. 5, 2025, each of which is incorporated herein by reference in its entirety.

### BACKGROUND

Circuit schematics provide the basic requirements of a circuit such as what components (e.g., transistors) it will have and how they ought to be connected. However, the details of these connections and the layout of these components is paramount to providing a circuit with the behavior desired by a circuit designer. The layout of circuit components can have dramatic effects on the performance of a circuit and determining the layout can require months of effort among teams of specialists. This may be true of circuits comprising of analog components, digital components, or a combination of both.

### SUMMARY

In an aspect disclosed herein is a method for optimizing a layout of an electronic circuit according to a parasitic capacitance, a parasitic resistance, or a matched wire percent time constant difference, comprising: (a) receiving an electronic circuit schematic and one or more target of the electronic circuit, wherein the electronic circuit schematic comprises a plurality of circuit components including at least one analog circuit component, and wherein the one or more target comprises the parasitic capacitance, the parasitic resistance, or the matched wire percent time constant difference; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically optimizing the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real number value and wherein the AI agent is trained to select actions to achieve an optimized score via the gameplay. In some embodiments, the AI agent is iteratively trained using a lookahead search comprising operations including: selecting a training action of the plurality of actions; determining a score for the training action of the plurality of actions based on one or more training target, generating a training datum comprising the training action of the plurality of actions and the score, wherein a training dataset comprises the training datum, and training the AI agent on the training dataset to optimize the score when selecting the action of the plurality of actions. In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target is provided by a user. In some embodiments, the method further comprises outputting a computer file configured to guide a fabrication of the electronic circuit. In further embodiments, the computer file is a .gds or .oa file. In some embodiments, the method further comprises (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the method further comprises: (g) outputting a .gds or .oa file of the layout of the electronic circuit, wherein the .gds or .oa file is configured to guide a fabrication of the electronic circuit. In further embodiments, the method further comprises fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In still further embodiments, the method further comprises displaying the layout of the electronic circuit on a graphical user interface. In some embodiments, the method further comprises displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the method further comprises displaying a success probability to a user based on the one or more target. In further embodiments, the success probability is output by a success probability network. In some embodiments, the operations further comprise refining the layout by performing one or more local modification to the layout.

In an aspect disclosed herein is a method for generating a layout of an electronic circuit, comprising: (a) receiving an electronic circuit schematic and one or more target of the electronic circuit, wherein the electronic circuit schematic comprises a plurality of circuit components including at least one analog circuit component; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically generating the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real number value and wherein the AI agent is trained to select actions to achieve an optimized score via the gameplay. In some embodiments, the AI agent is iteratively trained using a lookahead search comprising operations including: selecting a training action of the plurality of actions, determining a score for the training action of the plurality of actions based on one or more training target, generating a game replay comprising the action of the plurality of actions and the score, wherein a training dataset comprises the game replay, and training the AI agent on the training dataset to optimize the score when selecting the action of the plurality of actions. In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target comprises a matched wire percent time constant difference, a parasitic resistance, or a parasitic capacitance. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target are provided by a user. In some embodiments, the method further comprises outputting a computer file configured to guide a fabrication of the electronic circuit. In further embodiments, the computer file is a .gds or .oa file. In some embodiments, the method further comprises: (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the method further comprises: (g) outputting a .gds or .oa file of the layout of the electronic circuit, wherein the .gds or .oa file is configured to guide a fabrication of the electronic circuit. In further embodiments, the method further comprises fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In some embodiments, the method further comprises displaying the layout of the electronic circuit on a graphical user interface. In some embodiments, the method further comprises displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the method further comprises displaying a success probability to a user based on the one or more target. In further embodiments, the success probability is output by a success probability network. In some embodiments, the operations further comprise refining the layout by performing one or more local modification to the layout.

In an aspect disclosed herein is a method for training an artificial intelligence (AI) agent, comprising: (a) generating an electronic circuit schematic and one or more target; (b) generating a first training dataset via gameplay by performing a lookahead search using the AI agent, wherein the lookahead search comprises operations including: (i) selecting an action of a plurality of actions to update a layout of the electronic circuit, (ii) determining a score for the action of the plurality of actions based on the one or more target, and (iii) generating a game replay comprising the action of the plurality of actions and the score, wherein the first training dataset comprises the game replay; (c) training the AI agent using the first training dataset to optimize the score when selecting the action of the plurality of actions; (d) generating a second training dataset using the trained AI agent as in (b); (e) fine-tuning the AI agent using the second training dataset to optimize the score when selecting the action of the plurality of actions.

In some embodiments, the one or more target are sampled from a statistical distribution. In some embodiments, (d)-(e) are performed iteratively. In some embodiments, (d)-(e) are performed automatically without user intervention. In some embodiments, the AI agent is trained from scratch with no pre-existing training dataset. In some embodiments, the electronic circuit schematic comprises a plurality of electronic circuit components. In further embodiments, the plurality of electronic circuit components comprises at least one analog circuit component. In further embodiments, the plurality of electronic circuit components comprises a net. In still further embodiments, the net comprises a via or a metal wire. In some embodiments, the AI agent comprises a machine learning model configured to output a value, an action, or both. In further embodiments, the machine learning model is a neural network. In some embodiments, the AI agent comprises a success probability network. In further embodiments, the success probability network shares at least one neural network layer with a policy network or a value network. In some embodiments, the plurality of actions comprise determining a size of a circuit component of the plurality of circuit components, determining a placement of the circuit component of the plurality of circuit components, and determining a routing of a portion of the electronic circuit. In some embodiments, the one or more target comprises a matched wire percent time constant difference, a parasitic resistance, or a parasitic capacitance. In further embodiments, the one or more target is used to determine the score for the action of the plurality of actions, wherein the score comprises a calculation of the performance of the electronic circuit comprising the layout resultant from the action selected in (b)(i). In still further embodiments, the calculation of the performance comprises a comparison with an output of a post-layout extraction check (PEX), a simulation of an electronic circuit waveform, or a physics solver. In yet further embodiments, the score is further based on a design rule check (DRC) or a layout-versus-schematic check (LVS). In still further embodiments, the score is a continuous real number value. In some embodiments, the action of the plurality of actions is selected to optimize the layout according to the one or more target. In some embodiments, the lookahead search is configured to generate at least two game replays per iteration of (b). In some embodiments, the second training dataset comprises a portion of the first training dataset. In further embodiments, the first training dataset is stored in a buffer, and wherein the first training dataset is updated to become the second training dataset by removing or adding at least one game replay to the buffer. In further embodiments, the at least one game replay of the first training dataset is removed based on a recency of the at least one game replay, a novelty of the at least one game replay, or a loss of the at least one game replay. In some embodiments, the first training dataset, the second training dataset, or both comprise a human generated layout.

In an aspect disclosed herein is a computer-implemented system comprising at least one processor and instructions causing the at least one processor to perform operations, comprising: (a) receiving an electronic circuit schematic and one or more target of the electronic circuit, wherein the electronic circuit schematic comprises a plurality of circuit components including at least one analog circuit component, and wherein the one or more target comprises the parasitic capacitance, the parasitic resistance, or the matched wire percent time constant difference; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically optimizing the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real In some cases, the quality of a digital circuit number value and wherein the AI agent is trained to select actions to achieve an optimized score via the gameplay. In some embodiments, the AI agent is iteratively trained using a lookahead search comprising operations including: selecting a training action of the plurality of actions; determining a score for the training action of the plurality of actions based on one or more training target, generating a training datum comprising the training action of the plurality of actions and the score, wherein a training dataset comprises the training datum, and training the AI agent on the training dataset to optimize the score when selecting the action of the plurality of actions In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target is provided by a user. In some embodiments, the operations further comprise outputting a computer file configured to guide a fabrication of the electronic circuit. In further embodiments, the computer file is a .gds or .oa file. In some embodiments, the operations further comprise (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the operations further comprise: (g) outputting a .gds or .oa file of the layout of the electronic circuit, wherein the .gds or .oa file is configured to guide a fabrication of the electronic circuit. In further embodiments, the operations further comprise fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In still further embodiments, the operations further comprise displaying the layout of the electronic circuit on a graphical user interface. In some embodiments, the operations further comprise displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the operations further comprise displaying a success probability to a user based on the one or more target. In further embodiments, the success probability is output by a success probability network. In some embodiments, the operations further comprise refining the layout by performing one or more local modification to the layout.

In an aspect disclosed herein is a computer-implemented system comprising at least one processor and instructions causing the at least one processor to perform operations, comprising: (a) receiving an electronic circuit schematic and one or more target of the electronic circuit, wherein the electronic circuit schematic comprises a plurality of circuit components including at least one analog circuit component; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically generating the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real number value and wherein the AI agent is trained to select actions to achieve an optimized score via the gameplay. In some embodiments, the AI agent is iteratively trained using a lookahead search comprising operations including: selecting a training action of the plurality of actions, determining a score for the training action of the plurality of actions based on one or more training target, generating a game replay comprising the action of the plurality of actions and the score, wherein a training dataset comprises the game replay, and training the AI agent on the training dataset to optimize the score when selecting the action of the plurality of actions. In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target comprises a matched wire percent time constant difference, a parasitic resistance, or a parasitic capacitance. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target are provided by a user. In some embodiments, the operations further comprise outputting a computer file configured to guide a fabrication of the electronic circuit. In further embodiments, the computer file is a .gds or .oa file. In some embodiments, the operations further comprise: (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the operations further comprise: (g) outputting a .gds or .oa file of the layout of the electronic circuit, wherein the .gds or .oa file is configured to guide a fabrication of the electronic circuit. In further embodiments, the operations further comprise fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In some embodiments, the operations further comprise displaying the layout of the electronic circuit on a graphical user interface. In some embodiments, the operations further comprise displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the operations further comprise displaying a success probability to a user based on the one or more target. In further embodiments, the success probability is output by a success probability network. In some embodiments, the operations further comprise refining the layout by performing one or more local modification to the layout.

In an aspect disclosed herein is a computer-implemented system comprising at least one processor and instructions causing the at least one processor to perform operations, comprising: (a) generating an electronic circuit schematic and one or more target; (b) generating a first training dataset via gameplay by performing a lookahead search using the AI agent, wherein the lookahead search comprises operations including: (i) selecting an action of a plurality of actions to update a layout of the electronic circuit, (ii) determining a score for the action of the plurality of actions based on the one or more target, and (iii) generating a game replay comprising the action of the plurality of actions and the score, wherein the first training dataset comprises the game replay; (c) training the AI agent using the first training dataset to optimize the score when selecting the action of the plurality of actions; (d) generating a second training dataset using the trained AI agent as in (b); (e) fine-tuning the AI agent using the second training dataset to optimize the score when selecting the action of the plurality of actions.

In some embodiments, the one or more target are sampled from a statistical distribution. In some embodiments, (d)-(e) are performed iteratively. In some embodiments, (d)-(e) are performed automatically without user intervention. In some embodiments, the AI agent is trained from scratch with no pre-existing training dataset. In some embodiments, the electronic circuit schematic comprises a plurality of electronic circuit components. In further embodiments, the plurality of electronic circuit components comprises at least one analog circuit component. In further embodiments, the plurality of electronic circuit components comprises a net. In still further embodiments, the net comprises a via or a metal wire. In some embodiments, the AI agent comprises a machine learning model configured to output a value, an action, or both. In further embodiments, the machine learning model is a neural network. In some embodiments, the AI agent comprises a success probability network. In further embodiments, the success probability network shares at least one neural network layer with a policy network or a value network. In some embodiments, the plurality of actions comprise determining a size of a circuit component of the plurality of circuit components, determining a placement of the circuit component of the plurality of circuit components, and determining a routing of a portion of the electronic circuit. In some embodiments, the one or more target comprises a matched wire percent time constant difference, a parasitic resistance, or a parasitic capacitance. In further embodiments, the one or more target is used to determine the score for the action of the plurality of actions, wherein the score comprises a calculation of the performance of the electronic circuit comprising the layout resultant from the action selected in (b)(i). In still further embodiments, the calculation of the performance comprises a comparison with an output of a post-layout extraction check (PEX), a simulation of an electronic circuit waveform, or a physics solver. In yet further embodiments, the score is further based on a design rule check (DRC) or a layout-versus-schematic check (LVS). In still further embodiments, the score is a continuous real number value. In some embodiments, the action of the plurality of actions is selected to optimize the layout according to the one or more target. In some embodiments, the lookahead search is configured to generate at least two game replays per iteration of (b). In some embodiments, the second training dataset comprises a portion of the first training dataset. In further embodiments, the first training dataset is stored in a buffer, and wherein the first training dataset is updated to become the second training dataset by removing or adding at least one game replay to the buffer. In further embodiments, the at least one game replay of the first training dataset is removed based on a recency of the at least one game replay, a novelty of the at least one game replay, or a loss of the at least one game replay. In some embodiments, the first training dataset, the second training dataset, or both comprise a human generated layout.

In an aspect disclosed herein is one or more non-transitory computer-readable storage media encoded with instructions executable by one or more processors to provide an application executing the operations of: (a) receiving an electronic circuit schematic and one or more target of the electronic circuit, wherein the electronic circuit schematic comprises a plurality of circuit components including at least one analog circuit component, and wherein the one or more target comprises the parasitic capacitance, the parasitic resistance, or the matched wire percent time constant difference; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically optimizing the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real number value and wherein the AI agent is trained to select actions to achieve an optimized score via the gameplay. In some embodiments, the AI agent is iteratively trained using a lookahead search comprising operations including: selecting a training action of the plurality of actions; determining a score for the training action of the plurality of actions based on one or more training target, generating a training datum comprising the training action of the plurality of actions and the score, wherein a training dataset comprises the training datum, and training the AI agent on the training dataset to optimize the score when selecting the action of the plurality of actions. In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target is provided by a user. In some embodiments, the operations further comprise outputting a computer file configured to guide a fabrication of the electronic circuit. In further embodiments, the computer file is a .gds or .oa file. In some embodiments, the operations further comprise (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the operations further comprise: (g) outputting a .gds or .oa file of the layout of the electronic circuit, wherein the .gds or .oa file is configured to guide a fabrication of the electronic circuit. In further embodiments, the operations further comprise fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In still further embodiments, the operations further comprise displaying the layout of the electronic circuit on a graphical user interface. In some embodiments, the operations further comprise displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the operations further comprise displaying a success probability to a user based on the one or more target. In further embodiments, the success probability is output by a success probability network. In some embodiments, the operations further comprise refining the layout by performing one or more local modification to the layout.

In an aspect disclosed herein is one or more non-transitory computer-readable storage media encoded with instructions executable by one or more processors to provide an application executing the operations of: (a) receiving an electronic circuit schematic and one or more target of the electronic circuit, wherein the electronic circuit schematic comprises a plurality of circuit components including at least one analog circuit component; (b) selecting an action of a plurality of actions to update the layout of the electronic circuit with an artificial intelligence (AI) agent, wherein the plurality of actions comprise: (i) determining a size of a circuit component of the plurality of circuit components, (ii) determining a placement of the circuit component of the plurality of circuit components, and (iii) determining a routing of a portion of the electronic circuit; and (c) automatically generating the layout of the electronic circuit based on the action selected by the AI agent, wherein the AI agent is trained to select between at least two actions of the plurality of actions based on the one or more target, and wherein a target of the one or more target describes a desired performance of the electronic circuit.

In some embodiments, the AI agent is trained from scratch with no pre-existing training dataset. In some embodiments, the AI agent is trained solely via gameplay, wherein gameplay is used to iteratively generate a plurality of training datasets for training the AI agent. In further embodiments, a training dataset of the plurality of training datasets comprises a game replay, wherein a game replay comprises a state of the layout of the electronic circuit, an action selected to update the state of the layout of the electronic circuit, and a score for the selected action. In still further embodiments, the score is a continuous real number value and wherein the AI agent is trained to select actions to achieve an optimized score via the gameplay. In some embodiments, the AI agent is iteratively trained using a lookahead search comprising operations including: selecting a training action of the plurality of actions, determining a score for the training action of the plurality of actions based on one or more training target, generating a game replay comprising the action of the plurality of actions and the score, wherein a training dataset comprises the game replay, and training the AI agent on the training dataset to optimize the score when selecting the action of the plurality of actions. In further embodiments, the lookahead search comprises a single-step lookahead search, a multi-step lookahead search, or both. In still further embodiments, the single-step lookahead search comprises simulated annealing or an evolutionary algorithm. In still further embodiments, the multi-step lookahead search comprises a Monte Carlo Tree Search (MCTS), a graph or tree traversal algorithm, a best-of-n sampling algorithm, or a cross-entropy algorithm. In some embodiments, the one or more target comprises a matched wire percent time constant difference, a parasitic resistance, or a parasitic capacitance. In some embodiments, the one or more target is used to determine a score for the action of the plurality of actions, wherein the score comprises a calculation of the performance of the electronic circuit comprising the layout resultant from the action selected in (b). In further embodiments, the calculation of the performance comprises a comparison with an output of a post-layout extraction check (PEX), a simulation of an electronic circuit waveform, or a physics solver. In still further embodiments, the score is further based on a design rule check (DRC) or a layout-versus-schematic check (LVS). In further embodiments, the score is a continuous real number value. In some embodiments, the action of the plurality of actions is selected to optimize the layout according to the one or more target. In some embodiments, the one or more target are provided by a user. In some embodiments, the operations further comprise outputting a computer file configured to guide a fabrication of the electronic circuit. In further embodiments, the computer file is a .gds or .oa file. In some embodiments, the operations further comprise: (d) generating an evaluation of the layout of the electronic circuit to determine a performance of the electronic circuit comprising the layout versus the desired performance of the electronic circuit; (e) providing the layout and the evaluation to a user to receive an updated target; and (f) performing (a)-(e) until the user approves the layout of the electronic circuit. In further embodiments, the operations further comprise: (g) outputting a .gds or .oa file of the layout of the electronic circuit, wherein the .gds or .oa file is configured to guide a fabrication of the electronic circuit. In further embodiments, the operations further comprise fabricating the electronic circuit. In some embodiments, the plurality of circuit components comprise a net. In some embodiments, (b) is performed until each of the plurality of circuit components is used to update the layout of the electronic circuit. In some embodiments, the AI agent performs a lookahead search in (b) to select the action of the plurality of actions. In further embodiments, the lookahead search is based on an output of a machine learning model. In still further embodiments, the output of the machine learning model is an action, a value, or both. In some embodiments, the operations further comprise displaying the layout of the electronic circuit on a graphical user interface. In some embodiments, the operations further comprise displaying a distribution of a plurality of layouts generated by (a)-(c), wherein the distribution shows a performance of each of the plurality of layouts versus a target of the one or more target. In further embodiments, a user can interact with the distribution to display a subset of layouts of the plurality of layouts. In some embodiments, the operations further comprise displaying a success probability to a user based on the one or more target. In further embodiments, the success probability is output by a success probability network. In some embodiments, the operations further comprise refining the layout by performing one or more local modification to the layout.

In an aspect disclosed herein is one or more non-transitory computer-readable storage media encoded with instructions executable by one or more processors to provide an application executing the operations of: (a) generating an electronic circuit schematic and one or more target; (b) generating a first training dataset via gameplay by performing a lookahead search using the AI agent, wherein the lookahead search comprises operations including: (i) selecting an action of a plurality of actions to update a layout of the electronic circuit, (ii) determining a score for the action of the plurality of actions based on the one or more target, and (iii) generating a game replay comprising the action of the plurality of actions and the score, wherein the first training dataset comprises the game replay; (c) training the AI agent using the first training dataset to optimize the score when selecting the action of the plurality of actions; (d) generating a second training dataset using the trained AI agent as in (b); (e) fine-tuning the AI agent using the second training dataset to optimize the score when selecting the action of the plurality of actions.

In some embodiments, the one or more target are sampled from a statistical distribution. In some embodiments, (d)-(e) are performed iteratively. In some embodiments, (d)-(e) are performed automatically without user intervention. In some embodiments, the AI agent is trained from scratch with no pre-existing training dataset. In some embodiments, the electronic circuit schematic comprises a plurality of electronic circuit components. In further embodiments, the plurality of electronic circuit components comprises at least one analog circuit component. In further embodiments, the plurality of electronic circuit components comprises a net. In still further embodiments, the net comprises a via or a metal wire. In some embodiments, the AI agent comprises a machine learning model configured to output a value, an action, or both. In further embodiments, the machine learning model is a neural network. In some embodiments, the AI agent comprises a success probability network. In further embodiments, the success probability network shares at least one neural network layer with a policy network or a value network. In some embodiments, the plurality of actions comprise determining a size of a circuit component of the plurality of circuit components, determining a placement of the circuit component of the plurality of circuit components, and determining a routing of a portion of the electronic circuit. In some embodiments, the one or more target comprises a matched wire percent time constant difference, a parasitic resistance, or a parasitic capacitance. In further embodiments, the one or more target is used to determine the score for the action of the plurality of actions, wherein the score comprises a calculation of the performance of the electronic circuit comprising the layout resultant from the action selected in (b)(i). In still further embodiments, the calculation of the performance comprises a comparison with an output of a post-layout extraction check (PEX), a simulation of an electronic circuit waveform, or a physics solver. In yet further embodiments, the score is further based on a design rule check (DRC) or a layout-versus-schematic check (LVS). In still further embodiments, the score is a continuous real number value. In some embodiments, the action of the plurality of actions is selected to optimize the layout according to the one or more target. In some embodiments, the lookahead search is configured to generate at least two game replays per iteration of (b). In some embodiments, the second training dataset comprises a portion of the first training dataset. In further embodiments, the first training dataset is stored in a buffer, and wherein the first training dataset is updated to become the second training dataset by removing or adding at least one game replay to the buffer. In further embodiments, the at least one game replay of the first training dataset is removed based on a recency of the at least one game replay, a novelty of the at least one game replay, or a loss of the at least one game replay. In some embodiments, the first training dataset, the second training dataset, or both comprise a human generated layout.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents and patent applications incorporated by reference contradict the disclosure contained in the specification, the specification is intended to supersede or take precedence over any such contradictory material.

### BRIEF DESCRIPTION OF THE DRAWINGS

The novel features of the inventive concepts are set forth with particularity in the appended claims. A better understanding of the features and advantages of the present inventive concepts will be obtained by reference to the following detailed description that sets forth illustrative embodiments, in which the principles of the inventive concepts are utilized, and the accompanying drawings (also “Figure” and “FIG.” herein), of which:

FIG. 1 shows an example of a lookahead search;

FIG. 2A shows an example of a training flow for training machine learning models of an AI agent;

FIG. 2B shows an example of a production flow for using the machine learning models trained in FIG. 2A;

FIG. 3A shows an example of a setup stage of gameplay;

FIG. 3B shows an example of a placement stage of gameplay

FIG. 3C shows an example of a routing and an others stage of gameplay;

FIG. 3D shows an example of an evaluation stage of gameplay;

FIG. 4 shows an example of a gamer server;

FIG. 5 shows an example of a model server;

FIG. 6 shows an example of a layout game engine;

FIG. 7 shows an example of an AI agent;

FIG. 8 shows an example of a driver;

FIG. 9 shows an example of a computer system;

FIG. 10 shows an example of a web/mobile application provision system; in this case, a system providing browser-based and/or native mobile user interfaces;

FIG. 11 shows an example of a cloud-based web/mobile application provision system; in this case, a system comprising an elastically load balanced, auto-scaling web server and application server resources as well synchronously replicated databases;

FIG. 12 shows an example of a training mode for training a machine learning model of an AI agent;

FIG. 13 shows an example of a production flow mode of an AI agent;

FIG. 14A shows an example of a graphical user interface (GUI) of a computer system during production flow as described herein;

FIG. 14B shows an example of a graphical user interface (GUI) of a computer system during production flow as described herein;

FIG. 14C shows an example of a graphical user interface (GUI) of a computer system during production flow as described herein;

FIG. 14D shows an example of a graphical user interface (GUI) of a computer system during production flow as described herein;

FIG. 14E shows an example of a graphical user interface (GUI) of a computer system during production flow as described herein;

FIG. 14F shows an example of a graphical user interface (GUI) of a computer system during production flow as described herein;

FIG. 14G shows an example of a graphical user interface (GUI) of a computer system during production flow as described herein;

FIG. 14H shows an example of a graphical user interface (GUI) of a computer system during production flow as described herein;

FIG. 15A shows an example of an ideal voltage waveform output of a circuit; and

FIG. 15B shows an example of a simulated voltage waveform output of a circuit accounting for non-idealities.

### DETAILED DESCRIPTION

The systems and methods disclosed herein may facilitate the circuit layout design process. In some cases, the circuit may be an analog circuit. In some cases, the systems herein may execute machine-readable instructions stored on non-transitory computer readable media via one or more processors. This non-transitory computer readable media may comprise software instructions to execute the methods described herein or to deploy a system (e.g., comprising modules, engines, servers, etc.) as described herein.

In contemporary practice, the realization of an analog circuit from a circuit schematic may entail numerous rounds of iteration between an analog designer and a layout engineer. Generally, the layout design process comprises iterations of the following steps: (i) an analog designer provides a circuit schematic and requirements (e.g., a threshold of acceptable parasitic resistance between two pins of a component) of the circuit to a layout engineer, (ii) the layout engineer spatially organizes and connects components of the schematic to provide a layout for the circuit schematic, (iii) the analog designer evaluates the layout using mathematical or physical solvers to perform rigorous evaluations of the layout, and (iv) the analog designer accepts the layout or provides one or both of an updated circuit schematic or updated requirements to the layout engineer. In some cases, the process of analog layout design may require teams of analog designers and layout engineers, especially as the complexity of the analog circuit grows. Additionally, analog layout design provides unique challenges as compared to the ostensibly similar design of digital circuits. Analog circuits are significantly more prone to unpredictable non-idealities in behavior as a function of the organization of the circuit components (e.g., the layout). This is in part due to the greater sensitivity to noise of analog circuits as compared to digital circuits. For example, even small changes in voltage levels can significantly interfere with desired behavior analog circuits. Further complicating these considerations is the slow nature of the manual analog layout design process. A human layout engineer typically requires on the order of 6-20 hours (or more) to arrive at a single candidate layout for even simple circuit schematics. However, in part due to the sensitivity of analog circuits to component layout, it is unlikely that an initial layout engineer provided solution will satisfy the requirements of the analog designer after a first attempt, thereby leading to the iterative design process that continues until both analog designer and layout engineer arrive at an acceptable realization of the analog designer's circuit schematic. This process strains throughput in design and innovation in the field of analog circuit design. As described, this strain is in part due to temporal reasons (the back and forth between designer and engineer is slow). Further, such back and forth imposes economic burdens due to wasted labor costs. Still further, this process is largely limited by the expertise of layout engineers, who are limited in their capacity to generalize and apply their skill to the breadth of possible circuit schematics. Similarly, layout engineers are limited in their tolerance of complexity, where large analog circuits (e.g., >15 transistors) are often split into smaller problems and united for a final layout. This may introduce non-idealities that are difficult to account for as the process becomes increasingly atomized.

Accordingly, the systems and methods herein address each of these limitations by leveraging artificial intelligence agents to solve the layout problem through experience, or “game playing.” The systems and methods herein greatly accelerate the analog layout design process by facilitating the generation of up to thousands of layouts per second. Further, machine learning models of AI agents of these systems and methods can be trained over time, growing more competent at layout design as they are exposed to greater quantities of training data. An additional aspect of the training of these machine learning models that provides particular advantage is their lack of reliance on pre-existing training data. AI agents, interacting with a layout game engine to update states of analog layouts via actions, are scored for their actions based on the characteristics or behavior of the realized layout resultant from their actions. The actions of the AI agent such as placement of transistors, sizing of transistors, routing of nets among transistors, etc. can each be correlated with the ultimate behavior of the analog circuit. Accordingly, training sets may be established that compare the behavior of the analog circuit to behavior that was desired at the outset of layout design. By generating scores based in part on physics-rooted rigorous evaluation of realized circuits (e.g., all components placed, candidate final analog layout), the AI agent can learn which decisions led to analog circuits with desirable behavior, and which decisions led to poor analog circuits with undesirable behavior. This allows the AI agents to learn without human intervention or human-engineered training sets by providing a framework through which the AI agent can learn to take actions based on scores through trial and error. Further, a layout game engine as described herein with which the AI agent interacts may be configured to generate synthetic circuit diagrams, constraints, targets, etc., such that the AI agent can “play” the game of layout design without reliance on human provided constraints or targets. Such systems and methods are also capable of generating layouts holistically, not requiring the atomization of the layout process as the number of components increase. This may provide particular utility for non-analog layouts or mixed circuits (e.g., digital and analog components) that may comprise thousands of transistors.

### Overview

Herein are systems and methods for analog layout design using AI agents. In some cases, the AI agents may be trained through reinforcement learning. In some cases, the reinforcement learning may be a form of learning through gameplay. For example, the AI agent may learn to “win” at the game of analog layout design through collection of scores as a function of actions. In some cases, the collection of scores may be used for training machine learning models of the AI agent, thereby facilitating the AI agent in learning to suggest actions that achieve high scores. In some cases, the AI agent comprises one or more machine learning model or decision making algorithm. Such AI agents provide particular advantage due to their ability to learn without pre-existing training data. In analog circuit design, the acquisition of experimental or simulated analog circuit layout versus behavior data may be prohibitively expensive for training robust machine learning algorithms. This is in part due to the large, complex state space from which supervised machine learning algorithms would need to be trained. For such machine learning models to generalize beyond the training set, the training set should comprise samples representative of the breadth of possible values for each parameter, and likely combinations thereof. Obtaining such datasets to train machine learning models to satisfy analog layout design may be prohibitively expensive due to the complexity and breadth of the layout problem.

Herein, an AI agent may interact with a layout game engine capable of providing scores to the AI agent for the actions the AI agent selects. For example, during layout design, an AI agent can choose to place a transistor in a plurality of locations on a grid (e.g., representing a silicon chip/wafer). Each of the locations accessible to the AI agent may ultimately result in analog circuits with varying performances. The layout game engine may evaluate the quality of these placements in part by the quality of the circuits ultimately deriving from that placement. Accordingly, as part of their training, the AI agents can generate training data from scratch to learn how to predict which moves may be appropriate from a distribution of possible moves at a point in time. This process may be analogized to chess. For example, the first move in a chess game may have a strong correlation with a losing outcome. As such, an AI agent trained to play chess would almost never start the game by making that move, as it has learned that such a move frequently results in a loss. An analogous consideration can be made for good moves in chess resulting in wins. These considerations can be made for each turn of the chess game, accounting for the updating state of the game (e.g., as opponents move their pieces) and the possible legal options for moving chess pieces. Similarly, in analog layout design, the AI agent can learn that a particular placement, sizing, routing, etc., is likely to lead to a better outcome than an alternative choice. Generally, the quality of an outcome herein comprises at least an evaluation of a performance parameter of the analog circuit as compared to a user provided target. For example, a performance parameter may comprise a parasitic resistance, a parasitic capacitance, a time constant among matched wires, an analog circuit output waveform, a desired grid size, etc. These performance parameters may be reflective of the ideality of an analog circuit or its ideality as defined by a given user desiring particular performance parameters (targets). Further, in some cases, these performance parameters may currently be evaluable only by mathematical or physical solvers as their values (e.g., a resistance) or shapes (e.g., a waveform) are inextricable from and dependent on the layout of circuit components. In some cases, such performance parameters may comprise a portion of targets as described herein.

The systems and methods herein may be broken down into training and production flows. The training flow may comprise operations configured to train machine learning models to generate layouts of analog components. The production flow may comprise operations configured to query the models trained during the training flow to generate layouts for user provided circuit schematics or equivalent representations thereof. In some cases, layouts may be represented in software by an instance of an object class or an image of a schematic. In some cases, an output of a system or method herein may be a .gds (e.g., GDSII), .oa, or other configuration file type file. This may render the outputs compatible with EDA software. In some cases, the layouts generated by the systems and methods herein may be used directly to guide fabrication of circuits. For example, a GDSII file may be used to guide a fabrication of an electronic circuit.

### Learning Through Gameplay

AI agents as described herein may be trained via gameplay. In some cases, gameplay may be referred to as self-play as the AI agent is the sole “player” of the game. In some cases, gameplay may comprise a type of reinforcement learning. In some cases, reinforcement learning may comprise solving decision making problems with delayed scores through trial and error. Generally, gameplay comprises an iterative learning process by which an agent learns to perform actions based on scores. Such agents may be trained by playing games and receiving scores based on actions taken by the agent during gameplay. For example, herein, an AI agent may, at some point during the generation of an analog layout, place a transistor in the top left corner of a grid. For a given set of targets, the analog circuits dependent on this choice may generally result in excellent (e.g., near ideal) performance that satisfy the desired targets. Accordingly, the AI agent may receive a favorable score for this placement choice and trained to make similar choices for similar problems in the future. In some cases, a similar problem may comprise a problem with a similar set of targets, constraints, or states. For example, a user may later provide a circuit schematic or a set of constraints to the AI agent and request a layout satisfying a plurality of targets. In the course of placing components on a grid, the state of the circuit (e.g., a partially completed layout) may be similar to the state previously encountered during training. Accordingly, the AI agent may have learned to place the next component in manner as it did during training where the AI agent ultimately received a favorable score for the placement. In some cases, a favorable score may be a high score or a low score, depending on how the score is calculated. In some cases, a favorable score may be an optimized score. For example, an AI agent may be configured to optimize for a low score or a high score during training flow or production flow.

In some cases, the AI agent may be robust for generating layouts for familiar and unfamiliar circuit schematics. For example, a lookahead search may be implemented by AI agents to simulate consequences of their actions during inference. In some cases, a lookahead search comprises an evaluation of the benefit of a plurality of possible actions for updating layout state. In some cases, the evaluation of the benefit comprises gathering information about full layouts that follow from the possible actions or a subset thereof. For example, a lookahead search may comprise a Monte Carlo Tree Search (MCTS), which in some cases may comprise a rollout strategy for gathering information (e.g., statistics) about final layouts resulting from a possible action. Alternatively, the evaluation of the benefit may comprise selecting a plurality of actions based on a policy network, value network, or both, without simulating final layouts during action selection. In some cases, a lookahead search may comprise a best-of-n sampling. In some cases, a lookahead search may comprise simulated annealing. In some cases, a lookahead search comprise an evolutionary algorithm. In some cases a lookahead search may be a form of a cross-entropy method. In some cases, a lookahead search may comprise a tree or graph traversal algorithm. For example, a lookahead search may comprise a heuristically guided A* search or a beam search. In some cases, a lookahead search may comprise a combination of two or more of MCTS, best-of-n sampling, simulated annealing, an evolutionary algorithm, a cross-entropy method, or a tree or graph traversal algorithm. Generally, a lookahead search herein is configured to constrain exploration of a space of possible future states according to a measure of promise of a path. For example, a large number of actions for updating a state may be possible. Accordingly, for computational feasibility, a subset of actions may be explored based on a rule or heuristic. To illustrate, a value or policy may be used to select a subset of actions according to an expected score for the action. In some cases, lookahead search may comprise upper confidence bound algorithms. In some cases, lookahead search may comprise UCT or PUCT algorithms. In some cases, lookahead search may comprise a probabilistic rule that favors improvements while occasionally allowing worse outcomes to escape local optima.

Herein, an AI agent may simulate the consequences of a subset of actions by gathering information based on a candidate update to a given state of a layout. For example, a lookahead step from an MCTS or a simulated annealing algorithm may be used to determine whether an action should be performed to update the state of a layout. In some cases, the gathered information may be based on an action selected as a function of policy or value networks of the AI agent. In some cases, gathering information comprises gathering statistics. For example, an MCTS approach may gather score statistics for final layouts based on a potential action used to update layout state. In some cases, gathering information may comprise evaluation of a plurality of possible actions for predicted utility in achieving a final layout with a high score. For example, possible actions may be ranked based on a quality measure for states resultant from the possible actions. To further illustrate, simulated annealing may forgo the statistics-gathering of MCTS and instead make determinations on whether or not to accept an action/state update based on a direct evaluation of the actions/state updates. In some cases, a policy network may be used to predict a subset of actions from a plurality of actions that are likely to lead to a performant final layout. In some cases, a policy network may output an action for a given state of a layout. In some cases, the value network may output an expected score for a given state of a layout. In some cases, one or both of a policy or value network may be used to gather information during lookahead search so as to inform a final action selected by the AI agent. Generally, an action taken by the AI agent indicates a decision for how to update a layout during an iterative process of building a layout based on constraints and targets. Lookahead search may be used to gather potential scores for tens, hundreds, thousands, or tens of thousands of potential layouts resulting from a subset of actions prior to committing to a particular action. Accordingly, the AI agent may select an action based on thousands or more potential outcomes for each of a subset of actions. Such an approach may be used during training or production flows to provide robust AI agents trained without access to human knowledge or expert moves. AI agents trained in this manner may learn by gathering action-score data through their own decision making. This approach may provide further utility by foregoing biases of experts or humans by learning to solve the layout problem from scratch without relying on human gathered or engineered data. For example, a naïve model with randomly initialized weights may be adjusted through training on datasets of states, scores, actions, etc. via automated gameplay rather than through evaluation of human labeled datasets. Over rounds of training, the AI agent may improve a value, policy, or other network described herein through re-training, thereby making better decisions with better estimations of scores, a process that may be iterated to continually improve the models of the AI agent.

In some cases, the AI agent may implement a lookahead search algorithm to train the AI agent through gameplay or to select the next move during production or training flows. For example, in the context of generating layouts of analog circuits, the evaluation of an action's quality may depend on the likelihood that the action leads to an analog circuit with desired behavior. Given the broad range of potential actions from a given state, evaluating all possible outcomes for every action may be computationally prohibitive. Thus, the lookahead search algorithm may be configured to explore a promising subset of the search space. The AI agent, using lookahead search, may gather data regarding multiple potential outcomes from a given state by selectively exploring paths that are predicted to be likely to lead to desirable outcomes.

To illustrate lookahead search, the agent may determine which action to take based on statistical data about the likelihood of an action leading to a favorable result and its associated expected score. In some cases, the agent may rapidly select an action by evaluating a subset of possible actions based on prior knowledge, such as previously calculated probabilities and expected scores. Furthermore, the lookahead search algorithm may balance the trade-off between exploring new actions and exploiting the most promising ones. From a given state, the agent may simulate multiple outcomes for a likely action, and once confident in its evaluation, the agent may focus on alternative actions to gather further data. In some cases, the balance between exploring new actions and exploiting the most promising actions may provide particular utility by facilitating the discovery of successful search paths that may be relatively unexplored and thus naively predicted to have a low likelihood of success. For example, exploration of a relatively less explored or less likely path (e.g., by taking a moderate to low likelihood of success action) may be used to update prior knowledge regarding a state action pair. To illustrate, for a given state, adding a transistor to a particular region of a layout may be unexplored, but ultimately be determined to lead to a favorable score. Accordingly, calculated probabilities or expected scores for the state action pair may be updated such that the AI is more likely to select that action for that state. This balance between exploration and exploitation may provide particular utility by facilitating the search of a plurality of actions for a given state to mitigate myopic or repetitive decision making by the AI agent.

In some cases, a lookahead search may be configured to prioritize the evaluation of unexplored actions when an AI agent implementing the lookahead search has high confidence in the outcomes of previously evaluated actions. By doing so, the agent accumulates information on a range of possible actions. Such accumulation may facilitate selection of an action predicted to result in an optimized score. In some cases, this process may contribute to generating a local or sub-policy for a specific state, which can be used to refine the agent's overall policy output from a network. In some cases, a policy network may be described as learning a policy. For example, a policy may refer to a strategy for selecting an action from a state or determining a probability distribution over actions given states. As such, a local policy may be learned for a given state or subset of states and be used to update the policy network through training.

To illustrate, consider a partial layout of an analog circuit with two transistors. The AI agent, implementing a lookahead search, may evaluate placing a third transistor in various positions. Given the vast number of possible placements, evaluating each option may be computationally infeasible. Therefore, the lookahead search algorithm may be employed to focus on a subset of promising placements based on the likelihood and expected score of each. The agent explores the potential layouts resulting from the selected placements and gathers information on which configuration is most likely to lead to a high-score layout. In some cases, the information comprises statistical information. For example, MCTS may simulate final layouts and thereby determine a likelihood that a given action leads to a performant final layout based on gathered statistics. In some cases, the information comprises a plurality of actions most likely to lead to a performant layout without statistics gathering. For example, some instances of lookahead search may facilitate the selection of actions without implementing a rollout strategy. To illustrate, simulated annealing may provide a plurality of candidate layout perturbations, a subset of which may be accepted into the layout generation workflow. The AI agent can then select a promising placement based on these insights. This process may be iterated until all components are placed. In some instances, the system may evaluate 100, 500, 1,000, 1,500, 2,000, 2,500, or more potential layouts for a given state before determining the optimal action.

In some cases, learning or training through gameplay may comprise an AI agent interacting with a layout game engine. The AI agent may take as input a current state of a layout from a layout game engine and determine a next action to perform. The next action may be analogized to a move in a game. For example, the AI agent may select an action that it predicts will result in “winning” the game. Herein, winning may comprise receiving a large score by generating a layout that has behavior satisfying one or more target. The action selected by the AI agent may be sent to the layout game engine (or a manager thereof, e.g., a layout game engine) and be used to update the state. For example, the AI agent may decide to size a transistor to a particular width. The action to update this width may be sent to the layout game engine, which may update the state based on the action. The next action by the AI agent, for example, may be to place that transistor. Generally, herein, the AI agent has flexibility to determine the next action and is not predestined to perform certain types of actions for a given state or point in time. For example, the AI agent could place the transistor and subsequently size it rather than size then place the transistor. The AI agent may interact with the layout game engine, updating its state, until each of the components are sized, placed, routed, etc. Ultimately, upon reaching the final state (e.g., a realized layout), a score may be calculated and used to train a machine learning model of the AI agent.

In some cases, an action herein may comprise sizing a component, determining a number of fins of a transistor, determining a number of fingers of a transistor, selecting a pin variant of a component, shaping a component, placing a component, sizing a grid width, sizing a grid length, shifting a component, routing components, selecting a net to route, selecting a routing waypoint, configuring a net, rotating a component, adding a standard cell, moving a wire or net to another layer of a layout, removing a wire or a net, changing a transistor or component type, changing a grid size, synthesizing a clock tree, selecting a net material, selecting a pin location, or any other choice that may be made by a layout engineer during the analog layout design process. In some cases, after updating the state of a layout a DRC check, LVS check, PEX check, or other evaluation may be performed on a partial layout. In some cases, an evaluation of a partial layout may be used to prune a lookahead search.

In some cases, winning the layout game may be relative to one more target. In some cases, winning the layout game may be relative to a combination of one or more target and one or more constraint. In some cases, winning may be based on a score that is calculated based on a difference between a target and a performance or behavior of a realized layout. In some cases, a layout may win for a given set of targets and constraints despite not meeting one or more target. For example, an optimized score for a set of targets and constraints may correspond to a layout for which one or more target is not met. Generally, winning is case-specific and not predetermined. Such a description of winning may provide particular utility in a training flow as an AI agent may learn that winning is relative to a given problem. Additionally, such a description of winning may provide particular utility in a production flow by allowing a user to evaluate a plurality of layouts that may satisfy different combinations of targets rather than one layout with an optimized score. In some cases, winning may be according to a rank. For example, layouts may be sorted by score and a top n may be selected as winning. In some cases, a rank-based description of winning may provide particular utility by providing a relative basis for winning during a training flow. For example, if all targets cannot be met, a best or a top n layouts may be used for training rather than discarded as failing to meet all targets. In some cases, the outcome of the layout game may be non-binary. For example, winning may not be resolvable to “won” or “lost” and may instead be resolvable to a score relative to a comparison between one or more target and performance or behavior of a realized layout. In some cases, there may be multiple “winning” outcomes for a layout. For example, a score may be a continuous number value calculated from a plurality of user targets compared to realized performance or behavior of a circuit. As such, a score for one layout may be reflective of a give and take among targets. To illustrate, a targeted parasitic resistance may be achieved for a first layout while a targeted parasitic capacitance is not achieved for a first layout, but vice versa for a second layout. In this example, the first and second layout may have similar scores. In a training flow, this may be captured in game replays of a training set. In a production flow, both layouts may be presented to a user to guide their strategy for proceeding with layout design (e.g., go deeper into production flow or adjust targets, constraints). In some cases, winning may be user defined. For example, in a production flow a user can evaluate whether the AI agent has won the layout game by accepting or rejecting a layout generated by the AI agent.

The AI agent may comprise one or more network configured to output an action or a value. In some cases, an action may be selected from a probability distribution describing the likelihood of possible actions. In some cases, one or more neural network may learn a policy. In some cases, a policy may be analogized to a strategy. For example, given a partial layout and a plurality of actions, the policy learned by an AI agent may be configured to output which actions have the highest likelihood of achieving a favorable score. In some cases, a value network herein may output a value. In some cases, a policy network herein may learn a policy. In some cases, the policy network may be used to output an action. In some cases, the output of a policy network may be a distribution of the likelihood of a plurality of actions for a state. Accordingly, an action may be selected from the distribution based on a likelihood of that action. In some cases, the likelihood may be weighted. For example, a likelihood may be weighted by a visit count. In some cases, a network herein may refer to a neural network. In some cases, a network herein may refer to a machine learning model. In some cases, a single network may be configured to output both an action and a value. For example, a set of shared layers of a neural network may take as input a state of a layout and output both an action (or a distribution of actions) and a value. In some cases, the shared layers may be terminated by value specific layers or policy specific layers. In some cases, the policy network and the value network are two separate networks. For example, the policy network may be configured to determine one or more next action from a plurality of possible actions based on a learned likelihood of an action. In some cases, the likelihood may be based on scores gathered during training. In another example, the value network may be configured to predict an expected score for a given layout state. Generally, the policy network and value network may be used herein to guide lookahead search by selecting likely actions resulting in states with high expected score. In some cases, the policy network and value network share some components. For example, a backbone neural network may be configured to take as input a state of a layout and transform the state into a feature rich latent representation of the layout. The latent representation may be used as input into one or both of a policy head or a value head. As such, the same latent representation may be used to determine a next action or a value, depending on the task. In some cases, each machine learning model of an AI agent, or any subset of machine learning models of the AI agent, may share a backbone neural network.

In some cases, a value network may comprise a plurality of sub-networks. For example, a plurality of sub-networks may be used to predict a plurality of expected values for a layout to compare to one or more target. To illustrate, a first sub-network may be configured to output a parasitic capacitance for a layout and a second sub-network may be configured to output a parasitic resistance for a layout. In some cases, the output of the first sub-network or second sub-network may be compared to a target parasitic capacitance or target parasitic resistance, respectively. In some cases, a sub-network may be configured to output a plurality of expected values for a layout. For example, each net of a layout may connect to a pair of pins, each pair of pins having some degree of parasitic resistance between the pins. Accordingly, a sub-network for outputting parasitic resistance may output a plurality of parasitic resistances for the pairs of pins of a layout. In some cases, the output of a value network is a combination of values output by the sub-networks. For example, outputs of a plurality of sub-networks may be compared to targets, then added or otherwise mathematically combined to provide a value from the value network. In some cases, the values output by the sub-networks may be weighted. For example, failure to meet a subset of targets may be more strictly penalized than other targets.

In some cases, a value head may comprise a plurality of sub-heads. In some cases, a sub-head comprises one or more neural network layer appended to a backbone neural network. In some cases, a value network may be terminated with a plurality of sub-heads to output expected values for a layout. To illustrate, a first sub-head may be configured to output a parasitic capacitance for a layout and a second sub-head may be configured to output a parasitic resistance for a layout. In some cases, the output of the first sub-head or second sub-head may be compared to a target parasitic capacitance or target parasitic resistance, respectively. In some cases, a sub-head may be configured to output a plurality of expected values for a layout. For example, each net of a layout may connect to a pair of pins, each pair of pins having some degree of parasitic resistance between the pins. Accordingly, a sub-head for outputting parasitic resistance may output a plurality of parasitic resistances for the pairs of pins of a layout. In some cases, the output of a value network is a combination of values output by the sub-heads. For example, outputs of a plurality of sub-heads may be compared to targets, then added or otherwise mathematically combined to provide a value from the value network. In some cases, the values output by the sub-heads may be weighted. For example, failure to meet a subset of targets may be more strictly penalized than other targets.

In a first illustrative configuration of networks of an AI agent, the AI agent has a first network configured to learn a policy and output an action and a second network configured to output a value. In the first illustrative configuration, the first network and the second network do not share learnable parameters. For example, the first network and the second network may be trained separately to output an action and the value, respectively. To illustrate, the first network may have a plurality of neural network layers that are trained to output an action, while the second network may have an independent second plurality of neural network layers that are trained to output the value.

In a second illustrative configuration of networks of an AI agent, the AI agent has a backbone neural network that takes as input a state of a layout. The backbone neural network may be terminated with two sets of trainable neural network layers configured to learn a policy to output an action and a value. As such, the backbone neural network may be trained to learn a representation of the layout that is used as input into a first set of neural network layers for learning a policy and a second set of neural network layers for outputting a value. In some cases, the backbone neural network is trained on a loss function configured to minimize policy and value loss. In some cases, the first set of neural network layers is trained on a loss function to minimize policy loss only. In some cases, the second set of neural network layers is trained on a loss function to minimize value loss only.

In some cases, the AI agent may implement lookahead search. In some cases, lookahead search may be used to train the AI agent through gameplay. In some cases, lookahead search may be used to select a next move during production or training flows. In some cases, lookahead search may comprise single or multi-step lookahead search. In a game-the generation or optimization of layouts of analog circuits-the evaluation of a quality of an action may be dependent on the likelihood that the action results in an analog circuit with desired behavior. However, given the breadth of possible actions for a given state, determining all possible outcomes for each possible action may be prohibitively computationally expensive. As such, lookahead search may be configured to search a promising subset of the possible search tree. In some cases, lookahead search may be used to gather data (information) for a plurality of possible outcomes for a given state. For example, lookahead search may determine which action to take based on a gathered statistic about the likelihood of an action and an expected score for that action. In some cases, lookahead search may rapidly determine which action to take by evaluating a subset of possible actions based on a prior calculated probability of executing that action and an expected score for that action. In some cases, lookahead search may gather information about the appropriate action by balancing exploration of alternative actions versus exploitation of a most likely action. For example, from a given state, a certain action may be predicted to be most likely. The AI agent, via lookahead search, may simulate a plurality of possible outcomes for that highly likely state. After obtaining a high degree of confidence about the layouts resulting from that action, the AI agent may be configured to evaluate a different action rather than to continue evaluating the implications of the highly likely action. Accordingly, the lookahead search may be configured to forgo evaluating an action if it is already confident in the result of that action. As such, lookahead search may evaluate one of the alternative actions and the layouts ultimately resulting from that alternative action. In this way, lookahead search may gather information about a plurality of actions and output an action that it predicts will result in a high score based on that information. In some cases, lookahead search may determine a sub or local policy for a given state and use that sub or local policy to train the policy network of the AI agent. To illustrate, a partial layout may comprise two transistors. An AI agent implementing lookahead search may consider placing a third transistor in a plurality of positions. In some cases, there may be a large number of possible placements such that evaluating each placement option is computationally intractable. Accordingly, lookahead search may be used to search a subset of possible placements based in part on a likelihood of placements and an expected score for the placements. The AI agent may simulate, for the subset of placements, layouts that may result from each of the subset of placements and gather information about which placement is most likely to result in a high score layout. As such, the AI agent may ultimately select a next placement based on the information gathered through lookahead search. This process may be iterated until each component is placed. In some cases, 100, 500, 1,000, 1,500, 2,000, 2,500, or more layouts may be evaluated for a given state prior to an AI agent selecting an action.

In some cases, a lookahead search herein may comprise a single-step lookahead search. In some cases, an AI agent herein may implement a single-step lookahead search. A single-step lookahead search may be based on single-step layout perturbations and probabilistic acceptance thereof. For example, a given state of a layout may be evaluated for modifications. A modification may comprise deletion of a wire or movement of a component. In some cases, a lookahead search may comprise simulated annealing. A single-step lookahead search may iteratively propose modifications to a current layout and evaluate the resulting layout state. A proposed modification may be accepted or rejected based on a rule that favors improvements. In some cases, a proposed modification leading to a worse outcome may be permitted. This may be due to modification acceptance/rejection based on a probabilistic rule governed by an acceptable degree of variation. In some cases, an acceptable degree of variation may be correlated with a temperature parameter. Variation in accepted modification quality may facilitate efficient state-space exploration of the AI agent while avoiding local optima. This may provide particular advantage earlier in layout design where the effect of modifications is more challenging to predict. Over successive iterations, the agent may converge toward high-scoring layouts by increasingly favoring improvements. In some cases, a temperature parameter may be dynamically adjusted. Like other forms of lookahead search, simulated annealing may be used during training or production flows to guide the selection of actions based on anticipated layout quality. In some cases, a single-step lookahead search may comprise simulated annealing, an evolutionary algorithm, or combinations thereof. In some cases, a single-step lookahead search may be configured as a multi-step lookahead search. For example, a plurality of single-step lookahead searches may be run in parallel under different constraints and results therefrom compared to select an action. This may provide advantage as some single-step lookahead searches may be based on probabilistic techniques (e.g., simulated annealing). As such, configuring single-step lookahead searches as multi-step searches may be used to determine a nearer to global optimum from a probabilistic approach.

In some cases, a lookahead search may comprise a multi-step lookahead search. A multi-step lookahead search may comprise evaluation of a plurality of possible state updates from a current state. For example, MCTS may comprise a branching, tree-based search that explores possible future states resulting from a plurality of possible actions taken to update a current state. In some cases, a multi-step lookahead search may comprise MCTS, cross-entropy methods, tree or graph traversal methods, best-of-n sampling methods, or combinations thereof.

In some cases, single-step lookahead may be used to design a layout. In some cases, multi-step lookahead may be used to design a layout. In some cases, a lookahead search may combine single-step and multi-step lookahead search. For example, an MCTS approach may implement a multi-step lookahead search that determines a score for a candidate component placement by evaluating a plurality of final layouts evolving from the placement. For a later placement, a single-step lookahead search such as simulated annealing may be used. In some cases, the single-step lookahead search may be used to refine the placement. For example, a local perturbation of the placement may be predicted by simulated annealing to lead to a layout with a higher score. Component placement is provided to illustrate the combination of single and multi-step lookahead search, however other actions and refinements thereof may be readily considered.

In some cases, a lookahead search may comprise a neighborhood function. A neighborhood function may sample proposals for modification or perturbation for a lookahead search. For example, a wire may be re-routed or a component shifted to improve routing or placement-dependent performance of a layout relative to a target. In some cases, a neighborhood function may be used to modify a partial or final layout. In some cases, a neighborhood function may provide particular advantages in efficiency of layout generation or refinement. For example, a localized modification may be used on a partial or final layout to make minor adjustments rather than performing a rollback operation, whereby a rollback resets a layout to a prior state that is then subject to iterative placement or routing operations to again realize a final layout. Put simply, a neighborhood function may facilitate localized changes to a layout without requiring significant layout re-design. In some cases, simulated annealing may comprise a neighborhood function.

In some cases, an AI agent herein may take a state of the analog layout as input. In some cases, the state may be a 2D or 3D representation of the layout. In some cases, the 2D or 3D representation may have a structure similar to the layout. For example, a layer of a tensor representing the state of the layout may correspond to a layer of the analog layout. To illustrate, an analog circuit may have a three-dimensional organization of components and nets. As such, a layer of the state tensor may correspond to a layer of the circuit. In some cases, a layer may be a learned representation of the layout that is not analogous to the layers of the layout. For example, the state may be transformed by a representation function that encodes current or past states, observations, actions, or any combination thereof into a hidden state representative of the layout or the layout generation process. For example, the AI agent may not have access to a perfect model of the layout problem. In this context, a model of the layout problem may comprise rules for how a state may be changed. For example, the AI agent may learn what constitutes legal actions via scores rather than being restricted by the model explicitly. To illustrate, actions output by the AI agent may not be constrained by rules encoded in the layout game engine comprising the model of the layout problem. Instead, the AI agent may learn to take actions purely based on scores and update its policy or value networks accordingly.

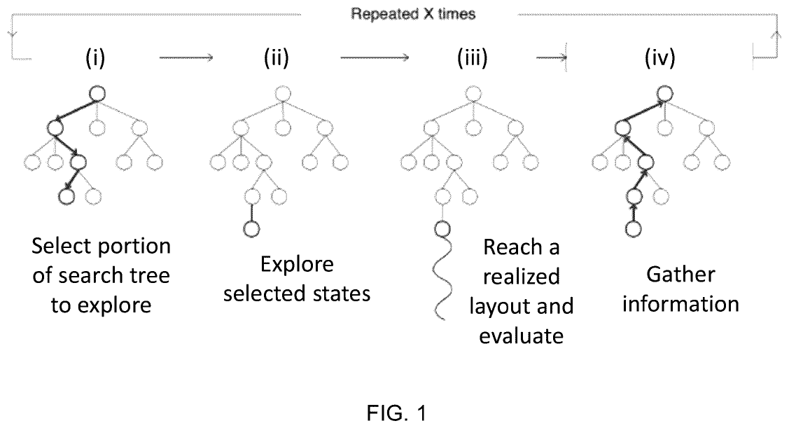

An illustrative lookahead search process may be illustrated by FIG. 1, which breaks lookahead search into (i) selecting a portion of the search space to explore, (ii) exploring the selected states, (iii) evaluating the selected states, and (iv) aggregating information to improve understanding and knowledge of the AI agent. (i) May comprise choosing a path in a search tree from a root node to a leaf node. In some cases, the root node may comprise an initial state (e.g., empty grid) or an intermediate state (e.g., partially layout). This may be performed by taking a path in the search tree based on an action-value (e.g., expected score based on a state resulting from an action) and an action output by a policy network weighted by a frequency with which a certain state has been visited. Accordingly, (i) may be dependent on the policy network, value network, or both as described herein. In some cases, the action-value may comprise predictions of the value network on the state resulting from the action. In some cases, revisiting an already explored state may become less informative as the consequences of that state become more certain. For example, a certain placement of a transistor may be likely as output by the policy network, but lookahead search may forgo that choice for a particular iteration of the search if prior iterations of that search have heavily explored that placement. In some cases, certain possible actions are rendered impossible by constraints. Generally, the balance between exploring likely versus less likely actions may be used to gather a training set of data representative of a wide breadth of possible state-action pairs. (ii) May comprise, upon reaching a certain depth of the tree (e.g., predetermined number of actions taken, an unsearched state), adding one or more nodes to the tree. In some cases, the one or more nodes may be states output by the policy network or random next states as determined by a rollout strategy. In some cases, a rollout strategy is configured to provide a random legal next move, a next move based on a rule, or a move selected based on an output of an AI agent. (iii) May comprise using the rollout strategy to reach a realized analog layout (e.g., all components placed) or use an evaluation function. For example, the rollout strategy may add components to the layout until a realized layout is achieved (e.g., all components added). This may provide a final layout for score calculation. In some cases, a rollout strategy may accelerate training as a random or heuristic selection of legal moves may be orders of magnitude faster than inference into policy or value networks as described herein while still providing an indication of likelihood of achieving a high score when multiple rollouts from a particular state are considered. For example, despite a potentially sub-optimal layout resulting from use of a rollout strategy, the layouts resulting from that state (or similar states) over many iterations of gameplay or rollout may be biased towards a particular score (e.g., high or low score). This may be reflected in training data and learned by a machine learning model during training. In some cases, an evaluation network may be used to evaluate at a certain depth of a search tree. In some cases, the evaluation function may be a separate machine learning model or comprise the value or policy network. In some cases, a rollout strategy and an evaluation network may be used in combination or during different phases of training. In some cases, (iii) may be an extension of (ii) rather than a separate operation. (iv) May comprise gathering statistics along the path of the tree from the realized layout to the root node (e.g., the initial state). For a decision tree as shown in FIG. 1 may represent, from the root node downwards, updating states of the layout as a function of actions. In (iv), states, actions, values, visit counts, etc. may be gathered in reverse order (e.g., from final layout to root) to obtain game replays that comprise data comprised of states, actions and score. In some cases, the statistics gathered may comprise visit count, estimated value, and accumulated scores of the nodes.

Generally, the gathered statistics may be used to update the value and policy networks through gradient descent or other machine learning optimization technique used for training machine learning models. In some cases, the gathered statistics may be used to train a success probability network. In some cases, a success probability network may be used to provide a number (e.g., percent) reflective of a percent probability that a target or targets will be satisfied by a layout. In some cases, the gathered statistics may be used to train a rollout strategy or evaluation network. The value network may be trained to predict an expected score for a given state based on past iterations of layout generation and data gathered therefrom. The policy network may be trained to predict a likelihood that a particular action may result in a favorable score (“winning” outcome). During training, each of the policy network and value network may be retrained after gathering of “game replays” and thus grow iteratively more accurate in predicting high value next actions and expected scores. For example, a randomly initialized model may pick actions at random and may arbitrarily predict scores. However, upon gathering scores based on actions and realized layouts, the policy network and value network may be trained to associate certain actions with scores and certain states with score. This training process may be performed an arbitrary number of times and provide models that continually improve over time. During inference, the policy and value models may work in tandem to provide rapid generation of layouts based on user targets. For example, an AI agent may simulate a plurality of outcomes based on the most promising paths as determined by the policy network cross-referenced with the value network. For example, as described above, an AI agent implementing lookahead search may evaluate potential actions based in part on outputs of a policy network and a value network. In some cases, an action of the policy may be analogized to an educated prediction and the predicted score of the state resulting from that action may be analogized to an evaluation of the consequences of that prediction.

In some cases, a policy network may be used in the generation of an initial layout. Initial layout generation may be done in a constructive, step-by-step manner. In some cases, an initial layout may serve as a starting point for further refinement. Further refinement may be conducted via local modifications to a final layout. For example, simulated annealing or other optimization methods may perturb the local structure of a layout to achieve further optimized behavior. For example, the policy network may be configured to sequentially select actions that place components and route connections based on learned associations between states and expected outcomes. Once a final or partially complete layout has been produced using the policy network, a search process such as simulated annealing may be applied to further improve the layout by moving components or modifying routed wires. This hybrid approach allows the AI agent to rapidly generate high-quality initial solutions using learned priors and then enhance them through fine-grained search, in some cases achieving better final outcomes than either method alone.

In some cases, the root node for lookahead search may comprise a partially completed layout. For example, a user may constrain the generation of layouts by providing a partially completed layout to which additional components are added. In some cases, the root node for lookahead search may be a reference layout. For example, a first batch of layouts may be presented to a user. The user may select a layout identified as promising. This promising layout may be used to constrain a second search. For example, the promising layout may be modified. In another example, new layouts may be generated with constraints derived from the promising layout.

In some cases, the policy network or value network may take as input a plurality of states. For example, as opposed to taking as input a current state (e.g., partially completed layout), an AI agent may determine an action to update the state based on the past n states of the layout. In some cases, the AI agent may take as input a plurality of past actions.

Evaluation of a layout may comprise a plurality of types of evaluation. Generally, evaluation may be performed to calculate a score. In some cases, the plurality of evaluations comprises a design rule check (DRC). In some cases, a design rule check may impose geometric constraints on a layout. For example, a DRC may comprise a sizing rule, a spacing rule, an enclosure or overlap rule, or other rule that physically constrains layout. For example, a DRC may dictate that a transistor may not be placed within x um of any other transistor. In some cases, a DRC check is performed after each state update to ensure lookahead search does not investigate impossible layouts. In some cases, a DRC check may evaluate whether a specific layout meets the constraints imposed by the process technology to be used for its manufacturing. In some cases, the plurality of evaluations comprises a layout versus schematic (LVS) check. In some cases, an LVS check may verify that the circuit schematic implied by the current layout is consistent with the originally provided constraints. For example, a circuit schematic may comprise a number of transistors and connections among pins of the transistors by nets. These factors may be considered inviolable constraints that the layout must adhere to. In some cases, the plurality of evaluations comprises a parasitic extraction (PEX) check. In some cases, a PEX check may comprise a rules-based or a fields-solver (e.g., physics solver) based determination of parasitic resistances or capacitances of an analog circuit.

The score may be a linear or non-linear combination of values. For example, a user may provide a plurality of parasitic capacitances, a plurality of parasitic resistances, a plurality of other targets, a plurality of design rules (e.g., DRC check), a circuit waveform, etc. Accordingly, an equation may be established to calculate the score based on these user provided aspects. In some cases, the equation may additionally comprise weights or ranks for aspects used to calculate the score. For example, randomly generated weights during a training flow or user provided weights during production flow may be used to bias the score. To illustrate, a user may require that two wires have a time constant difference of less than a certain percent threshold difference. The user may therefore heavily weight a target describing the threshold difference such that layouts with matched wire percent time constant differences below that threshold are heavily favored. Generally, the score may be a continuous real number value such that the definition of “winning” the layout game is flexible and case dependent.

In some cases, other forms of mathematical or physics solvers used for determining operating behavior of analog circuits may be used. In some cases, the solvers may be configured to output a signal or waveform of the analog circuit. In some cases, approximation models of any of the evaluation techniques may be used. For example, simplifications of rigorous physical solvers may be used to accelerate score calculation. In some cases, these approximations may use mathematical approximations. In some cases, these approximations may use machine learning models trained on data from rigorous physical solvers. For example, simulating behavior of a circuit may be slow as the mathematics/physics defining the circuit may be solved via simulation software that explicitly solves underlying equations defining the circuit. Accordingly, machine learning models may be trained on data from such simulation software such that inference into those machine learning models provides orders of magnitude faster estimations of circuit behavior. In some cases, the use of physical/mathematical approximations or machine learning approximations may provide particular utility by accelerating the calculation of scores during lookahead search. In some cases, a score may be based on a DRC check, an LVS check, a PEX check, a physical solver, an approximation of a physical solver, a circuit output signal or waveform, or any combination thereof.

Generally, evaluation may comprise comparison with an output of a type of evaluation and a target. In some cases, evaluation comprises determining a difference in an output of a type of evaluation and a target such as net to net (coupling) capacitance, a matched wire percent time constant difference, parasitic resistance, a parasitic capacitance, a layout width, a layout height, a proximity to well edge, transistor density, routing density, wire length, resistance between two pins, or other target. In some cases, a score may be a continuous value. For example, a score may be calculated based on an equation configured to compute a difference between one or more target and realized performance or behavior of an electronic circuit.

In some cases, evaluation may be changed depending on task. For example, a user may desire a quick estimation of a likelihood that a layout may be found for their combination of targets. As such, more approximate evaluation may facilitate faster search of potential layouts and their likelihood for providing a layout satisfying each of the targets. Alternatively, a user may commit to a set of constraints and targets and request the AI agent to find the best possible layout. As such, evaluation of the layouts may be configured to use less approximate evaluations to obtain a layout more precisely aligning with user targets. Such flexibility in evaluation may provide particular utility for users by providing a likelihood of success prior to contributing time or computational resources to generating a layout or layouts adhering to less approximate evaluations. In some cases, evaluation may be performed in a layout game engine as described herein. For example, upon an AI agent placing a final component, an evaluation of the layout may be performed in the layout game engine. In some cases, the evaluation data may be collected as a portion of a game replay and used for subsequent training.

### Training and Production Flows

### Training Flow

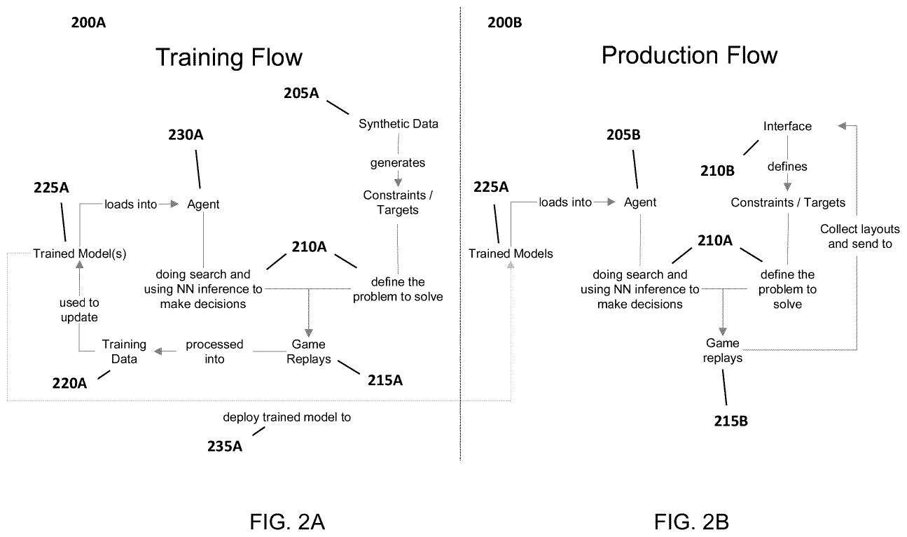

As shown in FIG. 2A the systems and methods herein may comprise a training flow 200A. The training flow 200A may comprise an operation of generating synthetic data 205A. Synthetic data 205A herein may generally indicate data that was not provided explicitly by a user. In some cases, the synthetic data 205A may obviate the need for pre-existing training data. For example, synthetic data 205A may be generated by software according to rules or heuristics configured to provide constraints or targets automatically through sampling of distributions of the same. In some cases, the sampling may be statistical. For example, a constraint or target may be sampled at random from a normal distribution or uniform distribution.

A constraint herein may comprise a number of active or passive components to place, a number of nets to route, a maximum current through a wire, one or more connection among components, a grid size or range of grid sizes, an electrical connection with an external component (e.g., power supply), a topological ordering of components, a layer in which a component is to be placed, an isolation structure to be placed about a specific component or components, or a circuit schematic. In some cases, a constraint comprises a power requirement of a circuit. In some cases, constraints may be automatically derived from a circuit schematic. For example, a pre-processing pipeline may be configured to convert a circuit schematic into a set of constraints. In some cases, a graphical user interface (GUI) may be configured for a user to build a circuit schematic. Accordingly, the circuit schematic may be represented by an object or other software data structure. In some cases, the grid may be rectangular, square, jagged, or any other geometric shape. In some cases, the grid may represent a chip or semiconductor wafer. In some cases, the constraints and the combinations thereof may be generated by the layout game engine. For example, the layout game engine may be configured to output legal combinations of constraints and targets for generating synthetic data 205A. In some cases, the layout game engine may comprise software instructions that guide the generation of synthetic data 205A such that the constraints may describe a functioning circuit, ideal or not. For example, the constraints may be configured to ensure that the number of components is appropriate for a particular grid size, or that the components are connected so as to complete a circuit, or that there are enough nets to connect the components, etc. In some cases, the synthetic data 205A may be used to automatically generate game replays 215A to train machine learning models as described herein. For example, the AI agent 230A may play the layout game based on the constraints and targets, ultimately arriving at datasets comprising constraints, targets, actions taken, scores, intermediate layout states, or combinations thereof. These game replays 215A may be used to train a policy or value network as described herein. In some cases, the constraints may be provided as a circuit schematic.

A target herein may comprise a desired performance metric of a circuit with a realized layout. In some cases, a target may provide a comparison for a realized layout with a desired performance of a layout. For example, a realized layout may be exposed to a PEX check and a calculated parasitic capacitance may be compared with a user parasitic capacitance target. In some cases, a target may comprise a parasitic capacitance, a parasitic resistance, a width of a layout, a height of a layout, a similarity in time constant between two wires (e.g., matched wires), a total capacitance of a single net, an output signal of an analog circuit, a max current through a wire, a symmetry of components, a vertical distance between components, a horizontal distance between components, a distance to a desired location of a component, a distance to a desired layer for a component, or any combination thereof. In some cases, a parasitic capacitance may comprise a coupling capacitance between two nets. In some cases, a parasitic resistance may comprise resistance between two pins. Generally, the targets during training may be used to determine a score of a realized layout. For example, an evaluation of behavior of a realized layout of analog components may be compared to the targets. For example, a target may be that a parasitic resistance between two pins of a transistor(s) is less than 1Ω. Accordingly, during gameplay, a plurality of layouts may be generated targeting the desired resistance of less than 1Ω and subsequently compared to the “true” resistance as determined by an evaluation of a layout's behavior.

To illustrate, synthetic data 205A may comprise a combination of targets selected from distributions of possible values for the targets. For example, a combination of targets may comprise pin1→pin5 resistance<0.2Ω, pin3→pin6 resistance<0.6Ω, net1→net2 coupling capacitance<10 F, and net 3→net5 matched within 10%. Accordingly, an AI agent 230A may be configured to generate layouts optimizing for this combination of targets.

In some cases, the combination of constraints and targets in synthetic data 205A may be used to define the problem to solve 210A by an AI agent 230A. For example, the problem to solve 210A may be to determine one, two, three, or more layouts that may satisfy or satisfy as best as possible the targets given the constraints. In some cases, 10, 20, 50, 100, 200, 500, 1,000, 2,000, 5,000, 10,000, or more possible layouts may be generated based on a datum (e.g., pair of constraints and targets) of the synthetic data 205A. In some cases, the problem to be solve 210A may be to generate a large number of layouts. In some cases, the problem to solve 210A may be to refine a plurality of layouts.

Still with regard to FIG. 2A, an AI agent 230A may be configured to solve the problem as previously described. For example, the AI agent 230A may be configured to place components on a grid and to do so by optimizing for the targets. In some cases, optimizing for the targets comprises predicting one or more next actions via a lookahead search using the targets to calculate scores. As in, given the current state and these targets, what action or actions are expected to provide an optimized score. The AI agent 230A may gather the results of a plurality of actions and their ultimate scores during training. A collection of the combination of actions, scores, and states may be referred to as “games” or “game replays” herein. In some cases, game replays 215A herein may be processed into training data 220A. As described herein, the scores and other information from the game replays 215A may be used to establish a loss based on the difference between actual outcomes and the AI agent's 230A predictions. Generally, the training data 220A comprising a game replay of game replays 215A may be used to update an untrained or trained machine learning model 225A. In some cases, the policy network of the AI agent 230A may be trained based on the games to predict a next action from a given state. In some cases, the value network of the AI agent 230A may be trained based on the games to predict an expected score from a given state. In some cases, a success probability network of the AI agent 230A may be trained based on the games to estimate a probability of success for a given set of targets and constraints. Upon updating, a trained machine learning model 225A may be uploaded into the AI agent 230A for additional rounds of training. In some cases, a trained machine learning model 225A may be deployed 235A to a production flow 200B. For example, a user may use a trained machine learning model 225A to generate a layout. In some cases, a trained machine learning model 225A may be one of a plurality of trained machine learning models (e.g., policy network, value network, success probability network, evaluation network, etc.).

In some cases, AI agent 230 may be trained to predict an incremental construction policy. For example, an incremental construction policy may comprise a consolidation or subset of actions taken during a simulated annealing or stochastic optimization process. This may provide advantage by decreasing the noise in layout design training data by decreasing wasted or redundant actions. For example, layouts generated via simulated annealing may undergo actions such as wire removal, wire re-routing, component placement adjustments, etc. As such, a policy may be learned on a more direct action path that what was used during layout design. For example, in some cases, even when simulated annealing or other stochastic optimization methods are used to generate training data, the AI agent 230A may be trained to predict an incremental construction policy rather than the exact modifications made during the optimization process. To further illustrate, while simulated annealing may involve actions such as moving a component or deleting a wire, the policy training may instead distill the final result into a clean incremental action sequence—such as placing a new component or routing a new wire. In this way, the policy network may learn to generate layouts from scratch in a step-by-step manner, informed by high-performing solutions discovered via a more exploratory path.

In some cases, a single-step lookahead search may comprise local modifications or perturbations to a partial or complete layout. For example, simulated annealing may be used to refine a layout and make local changes that provide overall improvements to a layout's quality. In some cases, such searches may be used to generate game replays. For example, a plurality of single-step lookahead search operations may be collected and used to train a policy network to predict a next action for updating a layout. In some cases, a policy network may be trained to provide a final layout along the same path reflected in the game replay. Additionally, or alternatively, a game replay may comprise a subset or consolidation of operations performed during a single-step lookahead search. For example, simulated annealing may provide random or semi-random modifications to a layout. As such, a more direct path from initial layout to final layout may be possible, and the game replay capturing this path may reflect the direct (consolidated) path. In some cases, this path may comprise a subset of operations of the single-step lookahead search, alternative operations that provide the same final layout, or a combination thereof.

In some cases, a trained machine learning model 225A of the AI agent 230A may be trained on hundreds of thousands, millions, tens of millions, hundreds of millions, or more game replays 215A. In some cases, a training data 220A may comprise 100 game replays, 1,000 game replays, 10,000 game replays, 100,000 game replays, 1,000,000 game replays, 10,000,000 game replays, 100,000,000 game replays, or more. In some cases, the game replays 215A may be batched during training. For example, in some cases, the game replays 215A may be batched into groups of about 100, 1,000, 10,000 or more game replays 215A per round of training.

In some cases, game replays 215A, training data 220A, or both may be supplemented by expert (human) curated examples. For example, a layout generated by a human for a set of constraints and targets may be used to train a machine learning model of AI agent 230A. In some cases, the layout generated by a human may be generated from scratch. In some cases, the layout generated by a human may be an adjustment or optimization of an output by AI agent 230A. In some cases, a layout generated by a human may be used at any stage of training. For example, a layout generated by a human may be used in a first stage of training. In another example, a layout generated by a human may be used in a final stage of training (e.g., fine-tuning). In some cases, a plurality of layouts generated by a human may be used throughout iterations of training. For example, a first training dataset, a second training dataset, or both may comprise a human generated layout.

### Production Flow

As shown in FIG. 2B, a trained machine learning model 225A of the training flow 200A may be deployed 235A into a production flow 200B. Generally, the production flow 200B comprises inference of trained machine learning models of an AI agent 205B. A trained machine learning model 225A may be exported from a training flow 200A based on an achieved level of performance or after a predetermined number of training iterations. For example, upon achieving a baseline level of performance, a trained machine learning model 225A may be further trained in the background and deployed to a software platform as later performance benchmarks are met. In the training flow 200A, a trained machine learning model 225A may be loaded into an AI agent 205B managing inference tasks. In some cases, a trained machine learning model 225A from the training flow 200A is incorporated into a production flow 200B while a copy of the trained machine learning model 225A is trained in the training flow 200A. Generally, the production flow 200B may be similar to the training flow 200A except that the user provides targets and constraints defining the problem to solve 210A by the AI agent 205B. In some cases, the AI agent 205B is a version of AI agent 230A. For example, a version of AI agent 230A may be deployed in the production flow 200B while a trained machine learning model 225A is updated in the training flow 200A. In some cases, the user provides constraints and targets via an interface 210B. In some cases, production flow game replays 215B may comprise a plurality of layouts and scores evaluable by a user on an interface 210B. In some cases, game replays 215B from the production flow may not be used to train a machine learning model of the AI agent 205B.

### Layout Exploration

In the production flow 200B, a user may receive a plurality of layouts generated by the AI agent 205B for a set of constraints and targets provided by a user. In some cases, layout exploration may comprise the search of a broader plurality of layouts. The AI agent 205B may be configured during inference to perform a greater breadth of search rather than a greater depth. For example, the AI agent 205B may prioritize providing layouts or layout statistics to a user to allow the user to gauge the likelihood of arriving at a layout meeting their targets. For example, a user may provide a circuit schematic and a plurality of targets that are infeasible to combine in practice. As such, the user may perform layout exploration to determine the distribution of likely accessible performance values (e.g., targets). The user may compare combinations of target values to determine the likelihood of obtaining that combination. This may provide particular advantage for users when considering the stringency of their targets. In some cases, this may inform the user that their circuit schematic is unlikely to have a layout associated with it that achieves their desired targets. To illustrate, a user may desire a particular percent match between time constants of two wires (e.g., of a net or pair of nets). Upon inferencing the AI agent 205B, the AI agent 205B may be used to provide distributions over the values of each of the targets corresponding to the frequency of layout with those target values within the batch of generated layouts. The user may then filter the batch of generated layouts to include only those which meet specific threshold values of each target (e.g., the percent match between time constants of two wires). The distributions of the other targets may be updated based on the filtering to highlight the overlap among the distributions for the filtered target. For example, the user may filter the generated layouts based on a threshold percent match between time constants of two wires. As such, the remainder of the distributions showing other target-based distributions may be filtered to show values of other targets that may be achieved in combination with the threshold percent match between time constants of two wires. In doing so the user can evaluate the trade-offs that exist between different targets in the batch of generated layouts. Based on this evaluation, the user may relax one of their provided constraints, add new constraints, provide a new or modified circuit schematic, or proceed further into the production flow 200B with the same set of constraints and targets.

In some cases, a circuit schematic may be an output of an electronic design automation (EDA) software. Generally, EDA software may comprise a category of software tools for designing electronic systems such as integrated circuits and printed circuit boards. In some cases, a circuit schematic may represent any analog circuit. For example, an analog circuit may comprise an operational amplifier (op-amp), an analog to digital converter (ADC), a digital to analog converter (DAC), a successive-approximation ADC, a low dropout (LDO) inverter, a bandpass filter, or other device. Generally, an analog circuit may be a circuit that takes as input or processes a non-binary or continuous signal.

In some cases, the AI agent 205B may be configured to output a probability that the AI agent 205B will determine a layout satisfying each of the targets provided by the user. In some cases, the probability of success is output by a trained neural network conditioned on the selected targets and constraints. This network may be trained based on the observed success of generated layouts for targets and constraints in game replays 215A used for training. Training this “success probability network” may take place alongside training the policy network and value network. The success probability network may share components with the value or policy network. In some cases, the success probability network may share a backbone neural network with a value network, policy network, or both. In some cases, the success probability network may be a standalone network. Rather than using the output of the success probability network directly, the success probability may be estimated by a fast search, for example, based on an initial, narrow search of complete layouts, shallow search of incomplete layouts, or both. In some cases, the output of the probability that the AI agent 205B may determine a final layout satisfying each of the targets provided by the user may be updated in real-time. For example, as a user updates targets or constraints in a GUI, the success probability may be calculated in parallel on a same or separate processor (e.g., remote server, cloud). In some cases, the success probability network is trained with the targets as input. In some cases, the success probability is trained with the targets and constraints as input.

In some cases, the user may relax their targets or update constraints via a graphical user interface (e.g., interface 210B). For example, a display of a computing device may comprise text boxes, sliders, dropdown menus, etc., from which a user can select or toggle targets or constraints. This interactivity combined with the success probability above may provide particular advantage by allowing users to rapidly gauge the likelihood of success for various combinations of desired targets prior to committing to a refinement of layouts.

In some cases, following generation of a plurality of layouts, a GUI of interface 210B may be configured to display a plurality of histograms or other graphs of distributions of the performance metrics of the circuits comprising the plurality of layouts. In some cases, the performance metrics may align with the desired targets. For example, among other targets, a user may desire a coupling capacitance between two nets of less than 1 F. The user may also desire a layout with a first transistor comprising a width of less than 50 μm. The AI agent 205B may generate a plurality (e.g., 10s, 100s, 1,000s) of layouts based on these targets. Histograms of the performances of the layouts may be shown to the user and may be configured to be interactive such that a user can be shown layouts corresponding to layouts with a particular performance or combination of performance metrics. For example, a user may interrogate the histograms to evaluate for an overlap of performance metrics such as layouts comprising the desired coupling capacitance and transistor width. Such analysis may also inform the user on how realistic their targets are. For example, if each layout comprising a coupling capacitance of less than 1 F has a first transistor width of 100 μm, the user may change or re-prioritize their targets.

In some cases, an AI agent 205B as described herein may be used to generate at least about 1, 2, 3, 4, 5, 6, 7, 8, 9, 10, 20 or more layouts per second, including increments therein. In some cases, the rate of layout generation may be relative to a single thread processor with 8 GB of RAM.

### Layout Refinement

In some cases, layout refinement may comprise a search for layouts with a greater penalty on misalignment between a behavior or performance of a layout and one or more target. In some cases, upon selection of a final set of constraints and targets, a user may desire a more exhaustive search of layouts to determine the most optimal layouts for the final set of constraints and targets. In some cases, layout refinement may use a more accurate evaluation of layouts. For example, more rigorous evaluations may be used during refinement to provide realized layouts with accurately predicted behavior or performance.

In some cases, layout refinement comprises a single-step lookahead search. In some cases, layout refinement comprises local perturbations of modifications of a layout to achieve improvements. This may provide particular advantage as a number of small, local refinements may provide a substantial aggregate improvement in final layout quality. In some cases, simulated annealing may be used to refine a layout.

In some cases, a user may select a plurality of layouts as encompassing the desired targets or comprising tolerable or near-tolerable deviations from the desired targets. As such, the user may indicate to the AI agent 205B that the AI agent 205B should prioritize similar or the same layouts. For example, the software configured to implement the methods herein may update the layout game engine with additional constraints to guide the AI agent 205B in taking actions that align with the layouts selected by the user. Additionally, or alternatively, the AI agent 205B may modify the layouts. For example, the AI agent 205B may re-size a transistor of a layout selected by the user. In some cases, refinement may comprise higher penalties on the search of layouts that deviate from a target. For example, a user may indicate that a particular layout width is highly desired. As such, the AI agent 205B may be configured to increase scores for layouts resulting in the desired width. For example, refinement of a layout may comprise the AI agent 205B completing layouts by placing, sizing, routing, etc., each component. As such, final evaluations of layout (e.g., scores) may be determined and provided to the user. In some cases, refinement comprises the use of more precise evaluations as described herein.

In some cases, a layout herein may comprise 10, 20, 30, 40, 50, 100, 1,000, 5,000, 10,000, 50,000, 100,000, or more components, including increments therein. In some cases, a layout herein may comprise a layout of a digital circuit. In some cases, a layout herein may comprise a layout of an analog circuit. In some cases, a circuit herein may comprise digital and analog components.

### Illustrative Layout Game

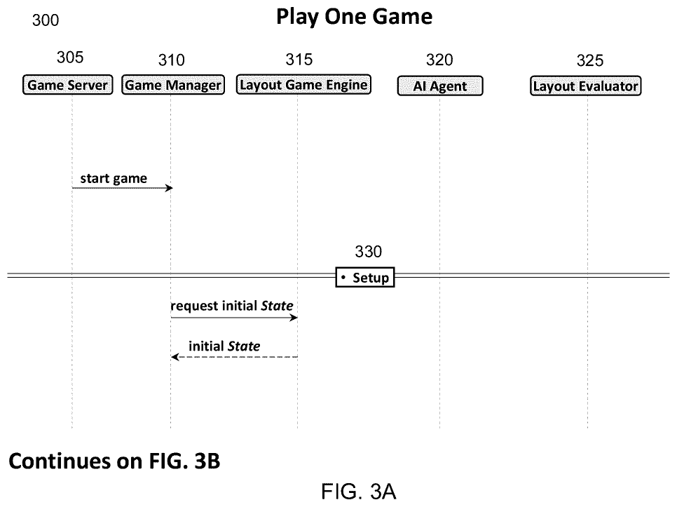

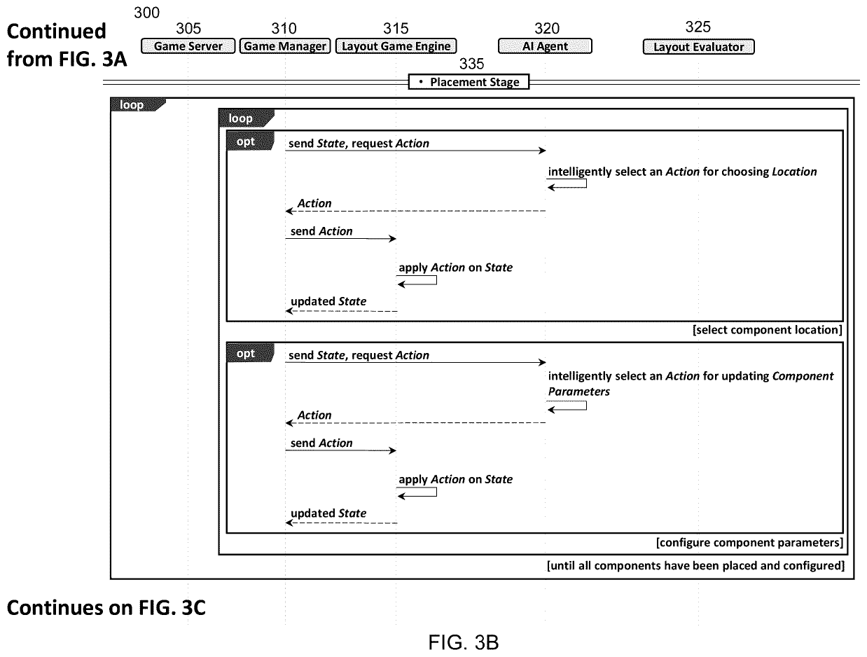

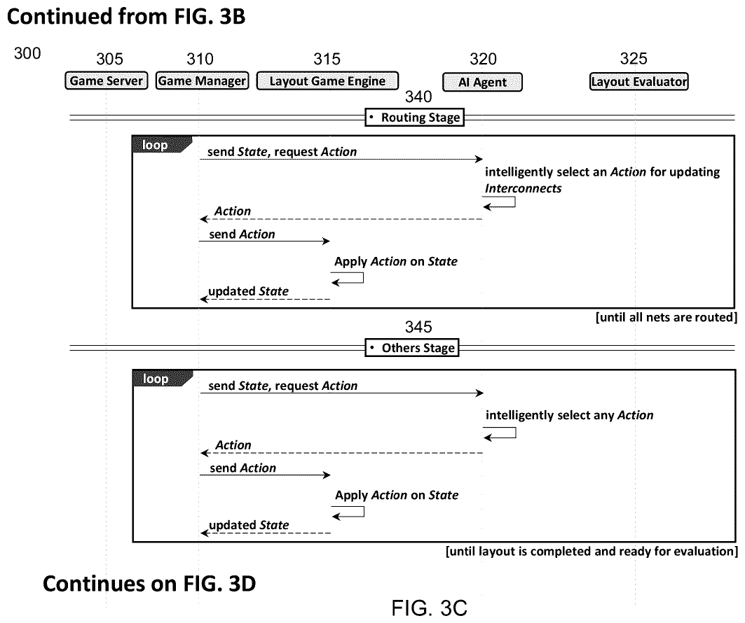

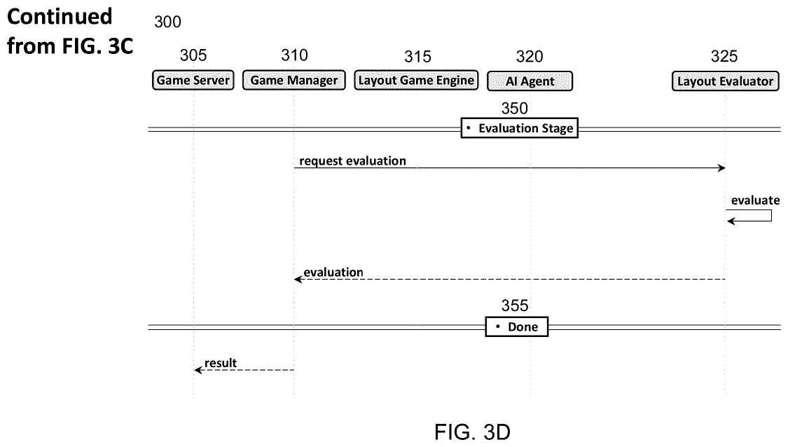

The game or gameplaying as described herein may be illustrated by FIGS. 3A-3D. Shown in FIGS. 3A-3D is one game 300 executed by a game server 305, a game manager 310, a layout game engine 315, an AI agent 320, and a layout evaluator 325. In some cases, a game may have stages comprising a setup stage 330, a placement stage 335, a routing stage 340, an others stage 345, an evaluation stage 350, a done stage 355, or combinations thereof.

As shown in FIGS. 3A-3D, a plurality of software modules, servers, and engines may be used to execute the layout game. The plurality of software modules, servers, and engines may be implemented on computer systems as described herein. In some cases, plurality of software modules, servers, and engines may be executed on one or more processors or computing devices. In some cases, plurality of software modules, servers, and engines may be executed in parallel or asynchronously. Generally, the plurality of software modules, servers, and engines may be configured to play a game based on targets and constraints by interaction of an AI agent 320 with the layout game engine 315 as described herein.

### Game Initialization

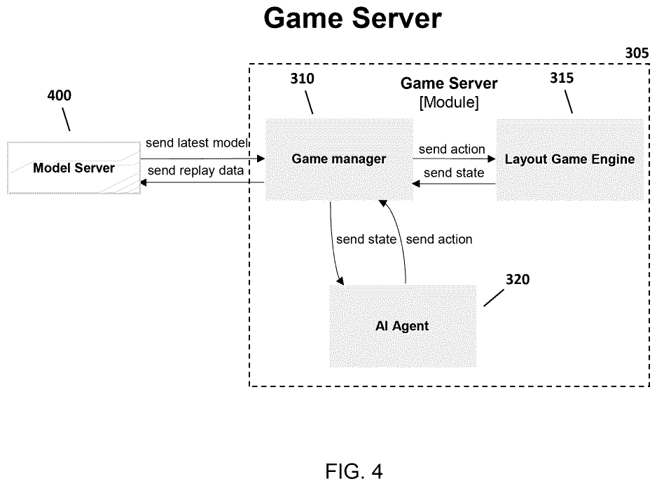

A game may be started by a game server 305 as shown in FIG. 3A. The game server 305 may pass game data comprising components, constraints, and targets to a game manager 310. In some cases, the components, constraints, and targets may be generated as synthetic data. In some cases, the components, constraints, and targets may be provided by a user. As shown in FIG. 4, the game server 305 may interface with an external model server 400 which provides the latest machine learning models for the AI agent 320 and may receive game replays from the game server 305. In some cases, the game manager 310 may comprise an API through which external servers (e.g., the model server 400) may interface. In some cases, the game manager 310 may manage communications between a layout game engine 315 and an AI agent 320. In some cases, a layout game engine 315 may be analogous to an environment in reinforcement learning. Generally, as described herein, the AI agent 320 may make decisions on which actions to take for updating the state. For example, the AI agent 320 may choose to place a transistor, size a transistor, route between components, etc. In some cases, the layout game engine 315 may store the current state, past states, or game rules. The game rules may comprise permanent or transient rules. For example, a user constraint may dictate a transient rule that may render certain actions illegal in the one game 300, but not games globally. In another example, a permanent rule may be a rule that applies to all games. For example, the types of components, legal ways of routing components, maximum grid sizes, etc.

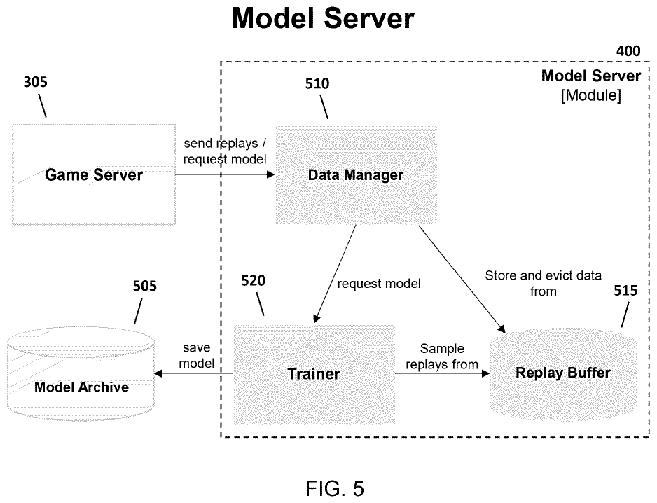

In some cases, a model server 400 as shown in FIG. 5 may communicate with a game server 305. The game server 305 may send game replays to the model server 400 or request models from the model server 400. In some cases, the model server 400 may be in communication with one or more databases forming a model archive 505. The model archive 505 may store checkpoints of machine learning models of the AI agent 320. The model server 400 may communicate with a data manager 510, a replay buffer 515, or a trainer 520. In some cases, the data manager 510 may comprise an API of the model server 400. In some cases, the data manager 510 may communicate with a replay buffer 515 to manage a plurality of game replays. For example, a game replay may be removed from the replay buffer 515 because it is old and thus generated by a less well trained version of the agent, it has a very low loss and thus is already well learned, it is similar to other data that already exists in the replay buffer 515 and thus provides little novel information, or the replay buffer 515 has a fixed size so older game replays may be removed to make room for newer game replays. Generally, the replay buffer 515 may be updated to comprise more recent data, less understood data, more diverse data, or any combination thereof. This may avoid training the machine learning models of the AI agent 320 on bad game replays or game replays generated with a past version of the AI agent 320. This may provide particular advantage as a replay buffer 515 may have a size limit. In some cases, the data manager 510 may request a model from the trainer 520. The trainer 520 may be configured to sample replays from the replay buffer 515. In some cases, the trainer 520 may be configured to process replays into a format amenable to training (e.g., feature and label sets). The trainer 520 may be additionally configured to process the replays into batches for training a machine learning model via gradient descent or other optimization technique. In some cases, the trainer 520 may save a trained model in the model archive 505.

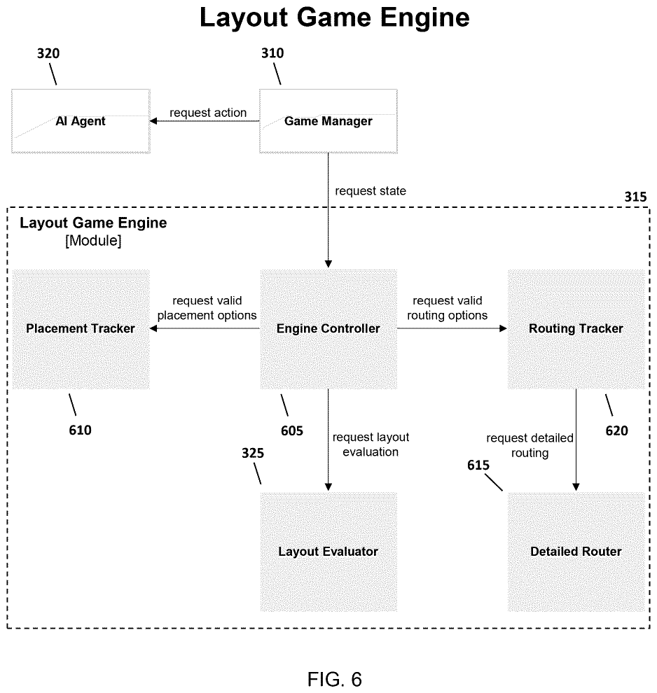

A layout game engine 315 may be a software module comprising a plurality of sub-modules as shown in FIG. 6. The layout game engine 315 may comprise an engine controller 605 sub-module, a placement tracker 610 sub-module, a layout evaluator 325 sub-module, a detailed router 615 sub-module, a routing tracker 620, or any combination thereof. The layout game engine 315 may take as input an action and output an updated state. The engine controller 605 of the layout game engine 315 may mediate the sub-problem solvers in the layout of the game engine. In some cases, the engine controller 605 may be the API for the layout game engine 315 module. In some cases, the sub-problem solvers may comprise the placement tracker 610, the routing tracker 620, or the layout evaluator 325. The placement tracker 610 may be configured to keep track of components to be placed and available spaces for placement. As such, the placement tracker 610 may be configured to provide valid placement options to the engine controller 605. In some cases, the routing tracker 620 may be configured to keep track of nets to be wired and available spaces for wiring. As such, the routing tracker 620 may be configured to return valid routing options to the engine controller 605. In some cases, the routing tracker 620 may further communicate with a detailed router 615 configured to determine metals for connecting components on the layout. As such, the detailed router 615 may be configured to return a detailed routing to the routing tracker 620. For example, the detailed router 615 may determine the geometry of a routing and a materials composition of the routing. In some cases, the detailed router 615 may be constrained by design rule check rules or constraints as described herein. In some cases, the layout evaluator 325 may be configured to evaluate layouts as described herein. As such, the layout evaluator 325 may be configured to return an evaluation of the layout as described herein. In some cases, the layout evaluator 325 may be configured to determine a score.

In some cases, a layout game engine 315 may be parallelizable. For example, the layout game engine 315 may be used to manage a plurality of games at once. In another example, expensive calculations such as PEX checks may be run in parallel by the layout game engine 315. Generally, the layout game engine 315 may be configured to manage states of a plurality of games and perform non-AI agent 320 computations in parallel or asynchronously to facilitate management of the plurality of games. In some cases, the layout game engine 315 may be in communication with or use a plurality of CPUs, GPUs, TPUs, or any combinations thereof.

Returning to FIG. 3A, the game manager 310 may initialize a game in a setup stage 330 and may request an initial state from the layout game engine 315. In some cases, the game manager 310 may generally manage game progress. In some cases, the initial state comprises an empty grid. In some cases, the initial state comprises a partial layout. In some cases, the initial state comprises a realized layout. For example, a user may desire to refine a complete realized layout. The layout game engine 315 may return the initial state to the game manager 310. In some cases, the initial state may comprise a plurality of tasks to complete. For example, targets, constraints, or both may be processed into tasks. To illustrate a task may be “place each component on the grid.”

### Placement Stage

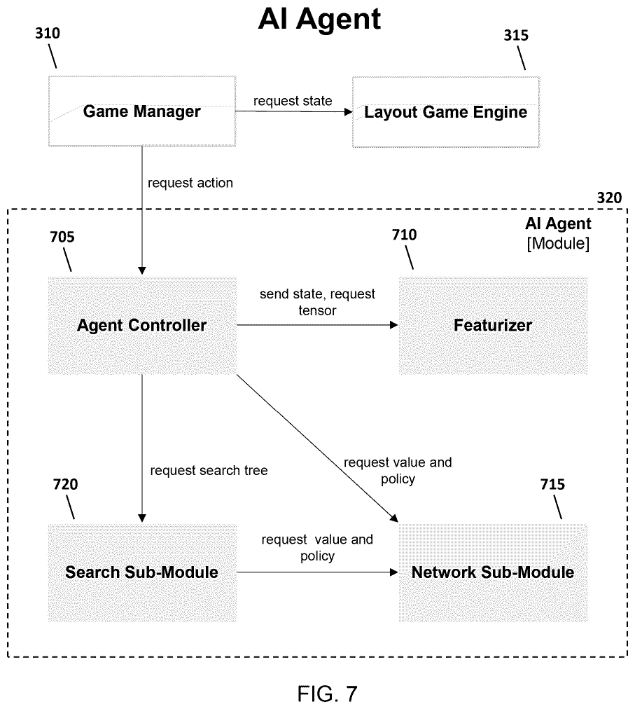

In some cases, one game 300 may comprise a placement stage 335, a routing stage 340, and an others stage 345 as shown in FIG. 3B and FIG. 3C, respectively. In some cases, the placement stage 335, the routing stage 340, the others stage 345, or both may perform actions dependent on the output of an AI agent 320. In some cases, the AI agent 320 may be as shown in FIG. 7. The AI agent 320 may receive a request for an action through an agent controller 705. The agent controller 705 may comprise an API of the AI agent 320. The agent controller 705 may additionally make the final prediction of the action with which to update the state of the layout. The agent of the agent controller 705 may request a tensor from a featurizer 710. The featurizer 710 may process the state into a format amenable to input into a machine learning model. In some cases, the machine learning model comprises a neural network. In some cases, the format comprises an array, a matrix, or a tensor. In some cases, the format comprises a 1D, 2D, 3D, 4D, or greater dimensional representation of the state of the layout. For example, in some cases, the state may be processed into a 3D tensor comprising layers of information. In some cases, an analog layout may comprise a plurality of layers of components. As such, a plurality of 2D layers of a data representation of the analog circuit may be stacked in a manner similar to the layers of the circuit itself. In some cases, the tensor returned may comprise a plurality of past states appended to the current state. Generally, the constitution and organization of the tensor may be adjusted to depend on the exact machine learning architectures used in the AI agent 320.

The AI agent 320 may also comprise a network sub-module 715. In some cases, the network sub-module 715 may comprise the machine learning models of the AI agent 320. In some cases, the machine learning models of the AI agent 320 comprise a policy network or a value network. In some cases, a machine learning model of the network sub-module 715 is a neural network. In some cases, the agent controller 705 may request a value or policy from the network sub-module 715. In some cases, the tensor of the featurizer 710 is passed to the network sub-module 715. In some cases, the network sub-module 715 may comprise a rollout policy or evaluation network.

In some cases, the agent controller 705 may be in communication with a search sub-module 720. The search sub-module 720 may implement a lookahead search as described herein. In some cases, the search sub-module 720 performs lookahead to improve a prior from a machine learning model of the neural network sub-module 715. In some cases, the search sub-module 720 may request a value or policy from the network sub-module 715. In some cases, the search sub-module 720 may comprise a rollout policy or rollout network or evaluation network as described herein. In some cases, the tensor of the featurizer 710 is passed to the search sub-module 720.

In some cases, the placement stage 335 may be entered following game manager 310 receipt of an initial state. In some cases, the placement stage 335 may comprise one or more loop. In some cases, a loop may comprise operations including selecting a component parameter of a component, selecting a location of a component on a layout grid or a combination thereof. For example, as shown in FIG. 3B, following a game manager 310 request for an action from an AI agent 320, a loop may be executed to select a component parameter and place components. In some cases, a component parameter and a location of a component may be selected in a shared loop. In some cases, component parameter selection and component placement may be performed using two or more loops. In some cases, a subset of component parameters are selected and placed upon execution of a loop. In some cases, a loop indicates an iterative update of a state of a layout by actions selected by an AI agent 320. A placement stage 335 as described herein may comprise a loop configured to execute operations including (i) sending a request for an action to update a state of the layout from the game manager 310 to the AI agent 320, (ii) intelligently selecting an action to update a state of a layout with an AI agent 320, (iii) communicating the selected action back to the game manager 310, (iv) using the game manager 310 to communicate the action to the layout game engine 315, (v) updating the state of the layout based on the selected action with the layout game engine 315, and (vi) communicating the updated state back to the game manager 310. The placement stage 335 may comprise a loop that iteratively sends a current state to the AI agent 320 with a request for a next action. The AI agent 320 subsequently returns at least one action to the game manager 310, which forwards the action to the layout game engine 315. In some cases, the action may comprise determining coordinates to place a component. In some cases, the action may comprise selecting a component parameter. In some cases, the action is determined via lookahead search. In some cases, the actions of the AI agent 320 may be constrained by user requirements (e.g., constraints) or design rules (e.g., of a design rule check, DRC). The layout game engine 315 may update the state of the analog layout. In some cases, updating the state of the analog layout comprises updating the state with spatial or routing information. This may be used to prevent overlapping components or intersection of routings between components. This updated layout may be passed to the game manager 310. The process shown in the loop of FIG. 3B may be repeated until one or more component parameter and location is selected for each component.

In some cases, selecting a component parameter may comprise selecting an action to update a height of a component or a width of a component. In some cases, selecting a component parameter may comprise sizing a component. For example, an area of a component may be updated but a height to width ratio retained. In some cases, selecting a component parameter may further comprise determining a number of fins of a transistor, determining a number of fingers of a transistor, selecting a pin variant of a component, selecting a pin location, shaping a component, changing a transistor or component type. In some cases, a DRC check, LVS check, PEX check, or other evaluation may be performed on a partial layout after updating the state of the partial layout.

In some cases, the action is selected to update a state of a layout. In some cases, the updated state of the layout may comprise an input to the AI agent 320 when selecting the next action.

In some cases, selecting a location may comprise determining coordinates at which to place a component. In some cases, selecting a location may be associated with updating a constraint on the AI agent 320. For example, the AI agent 320 may not place overlapping components in a same layer of a layout. In some cases, a DRC may be used to evaluate the validity of a placement.

In some cases, following selection of a component parameter and a location, a description of a component may comprise a base structure with gates, power sources, power drains, and connection points (pins) accessible during the routing stage 340. In some cases, layout trimming may be performed prior to the routing stage 340. In some cases, layout trimming may be used to remove excess or unused space from a layout grid.

### Routing Stage

As shown in FIG. 3C, a routing stage 340 may follow the placement stage 335. In some cases, however, the routing stage 340 may be interspersed with the placement stage 335. For example, a net may be routed among components prior to placement of all components. Alternatively, all placements may be performed prior to the wiring of the nets. In the example shown in FIG. 3C, the routing stage 340 may comprise two options.

The routing stage 340 may comprise a similar state, action, update flow of operations as described for the placement stage 335 (e.g., operations (i)-(vi)). In some cases, an action selected by the AI agent 320 may be to update an interconnect between or among components. For example, the AI agent 320 may change a routing between components. In some cases, an action selected by the AI agent 320 may be to select a next net to route. In some cases, an action selected by the AI agent 320 may be a selection of a plurality of next nets to route. In some cases, an action selected by the AI agent 320 may be a material of a net. For example, the AI agent 320 may be used to select a type of metal used to form a net. In some cases, an action selected by the AI agent 320 may be to determine a path of a net. In some cases, an action selected by the AI agent 320 may be to determine a coordinate through which the net must pass. In some cases, the AI agent 320 may be used to update an interconnect within a component. In some cases, the net may be routed by a detailed router 615. In some cases, the detailed router 615 may be as described in FIG. 6. In some cases, the layout game engine 315 actuates the update on the state. In some cases, the actions selected by the AI agent 320 in the routing stage 340 may optimize for alignment of a realized layout with a target. For example, a matched wire time constant difference may depend in part on the path of a net. In another example not shown, an action of the routing stage 340 may be forced. For example, there may be only one viable option for routing. Alternatively, the user may have constrained the game to require a particular routing.

In some cases, the AI agent 320 may have a separate machine learning model or models for routing. In some cases, routing may be performed based on path finding or traversal algorithms. For example, the A* algorithm may be implemented to perform a weighted search between two points. To illustrate, a path between two pins may be selected based on a measure of optimality of paths between the two pins, where the optimality of a path is dependent in part on factors other than path length. For example, a path may be selected based on spatial constraints such as wire to nearest component distance. To illustrate, a routing of a net may penalize short distances if they place a wire of the net within x um of a transistor. In some cases, routing may be performed to minimize resistance along a wire or capacitance between wires. In some cases, the routing may be in two or three dimensions. For example, an analog layout may have a plurality of layers. As such, a net comprising the wire may be connected to more than one layer. Generally, the routing of the routing stage 340 may route all nets (e.g., on a global or subset basis), iteratively, until the routing of all of the nets is complete.

In some cases, there may be a plurality of routers. For example, a more computationally intensive router may be called when a particular net comprises a user target. Alternatively, a more naïve, faster router may be called when a risk of violating a target is low. For example, a short, simple net between a power source and a proximal first transistor may have a small variation in behavior among a plurality of possible routings. In some cases, an AI agent 320 may be used to select a path for a net. For example, a net dependent target may depend on the path of the net taken when connecting components. As such, an AI agent 320 or other routing technique herein may determine a path of a net.

### Others Stage

In some cases, an others stage 345 may comprise selecting an action of a plurality of actions as described herein. As in the placement stage 335 or the routing stage 340, the others stage 345 may comprise iterative requests by the game manager 310 for actions selected by the AI agent 320 to update the layout state (e.g., operations (i)-(vi) described for the placement stage 335). In some cases, the others stage 345 may be used to update a layout until a stopping condition is met. In some cases, the stopping condition may be met when an AI agent 320 predicts no actions that would lead to an improvement of the layout. In some cases, the stopping condition may be met when a layout is complete. In some cases, the stopping condition may be met when a pre-determined number of loop iterations are met. In some cases, the stopping condition may be met when a time limit is exceeded. In some cases, a stopping condition may be met when a change in score over a past number of iterations is below a threshold. In some cases, the others stage 345 may select an action from a plurality of actions comprising determining a number of fins of a transistor, determining a number of fingers of a transistor, selecting a pin variant of a component, sizing a grid width, sizing a grid length, shifting a component, routing components, selecting a net to route, selecting a routing waypoint, configuring a net, rotating a component, adding a standard cell, moving a wire or net to another layer of a layout, removing a wire or a net, changing a transistor or component type, changing a grid size, synthesizing a clock tree, selecting a net material, selecting a pin location, or any other choice that may be made by a layout engineer during the analog layout design process. In some cases, a DRC check, LVS check, PEX check, or other evaluation may be performed on a partial layout.

### Evaluation Stage

Evaluation of layouts with regard to the evaluation stage 350 illustrated in FIGS. 3A-D and evaluation as described generally herein may be described as follows. In FIG. 3D, a layout that has had each component placed and connected (e.g., routed) may be evaluated. The game manager 310 may request that the layout evaluator 325 determine a score for the layout. This evaluation may be returned to the game manager 310, which may be returned to the game server 305. In production flow, the score may be dependent on a user provided target.

The layout evaluator 325 may comprise a plurality of evaluations. In some cases, the plurality of evaluations comprises a design rule check (DRC). In some cases, the plurality of evaluations comprises a layout versus schematic (LVS) check. In some cases, the plurality of evaluations comprises a parasitic extraction (PEX) check. In some cases, the plurality of evaluations comprises an output of a physics or mathematical solver. In some cases, the plurality of evaluations comprises a simulation of analog circuit behavior. For example, a simulation may be performed to determine a percent difference between time constants of two matched wires. In another example, the simulation may comprise a determination of an output waveform resultant of an analog circuit. In some cases, an output of an evaluation of the plurality of evaluations compared to a target. For example, a PEX check may determine a behavior of a realized layout and serve as a basis for comparison with a target. As described, this comparison may be used to train machine learning models of the AI agent 320. For example, the plurality of evaluations may be used to build a score which may be used for training. In some cases, a score comprises a linear combination of differences among targets and behavior or performance of a realized layout. In some cases, the comparison may be a more complex mathematical comparison among targets and realized layout behavior. For example, a comparison of a target waveform and a waveform of a realized layout may comprise a plurality of sub-comparisons or summary statistics such as average difference or variance. Generally, a score may be used to gauge an overall quality of the layout as defined by the targets. In some cases, some targets may be weighted in a score calculation. For example, a user may have a lower priority target. In some cases, the user may have a target that is more important to the user to satisfy.

Generally, an evaluation may comprise a comparison of a realized layout with a target. In some cases, the evaluation may comprise calculating a score based on one or more comparison between a performance or behavior of a realized layout and a target. In some cases, an evaluation may comprise a comparison between a behavior or performance of a realized layout and one or more targets comprising a parasitic capacitance, a parasitic resistance, a width of a layout, a height of a layout, a similarity in time constant between two wires (e.g., matched wires), a total capacitance of a single net, an output signal of an analog circuit, a max current through a wire, a symmetry of components, a vertical distance between components, a horizontal distance between components, a distance to a desired location of a component, a distance to a desired layer for a component. In some cases, a comparison may be a difference or a ratio between a target and a performance or behavior of a realized layout. In some cases, a plurality of comparisons may form a mathematical expression for calculating score.

In some cases, a done stage 355 may comprise passing the result from the game manager 310 to a game server 305. In some cases, the result may comprise the evaluation of the layout to be presented to a user or stored in a game replay for training. In some cases, the constraints, targets, components, actions, or scores, may comprise a portion of the result. In some cases, the result may be used to generate a GDSII or other layout file. The result may comprise a representation of the layout comprising coordinates of components and connection points for nets. Generally, the result comprises a complete description of the layout such that it may be presented to a user on GUI or used to fabricate a circuit.

In some cases, component parameter selection, location selection, or any other action to update the state may be performed in any order. For example, a component may be placed and then sized via component parameter selection. In some cases, routing may be interspersed with component parameter selection or location selection. For example, a subset of components may be routed prior to placement of all components. In some cases, operations of the others stage 345 may be interspersed with operations of the placement stage 335 or the routing stage 340. Generally, the illustrative layout game shown in FIGS. 3A-3D is to illustrate the concepts of the layout game via example. For example, the layout game may comprise a single loop or any number of loops for action selection. To illustrate, the AI agent 320 may be configured to select any action from the plurality of actions comprising determining a number of fins of a transistor, determining a number of fingers of a transistor, selecting a pin variant of a component, sizing a grid width, sizing a grid length, shifting a component, routing components, selecting a net to route, selecting a routing waypoint, configuring a net, rotating a component, adding a standard cell, moving a wire or net to another layer of a layout, removing a wire or a net, changing a transistor or component type, changing a grid size, synthesizing a clock tree, selecting a net material, selecting a pin location, or any other choice that may be made by a layout engineer during the analog layout design process. In some cases, a DRC check, LVS check, PEX check, or other evaluation may be performed on a partial layout after a state of the layout is updated.

For example, an evaluation may be performed after an action selected by the AI agent 320 is used to update the state of the layout. To play the layout game, the AI agent 320 may generally perform operations (i)-(vi) as described for the placement stage 335, where the action selected by the AI agent 320 is not constrained to a specific category of action.

### Illustrative Driver

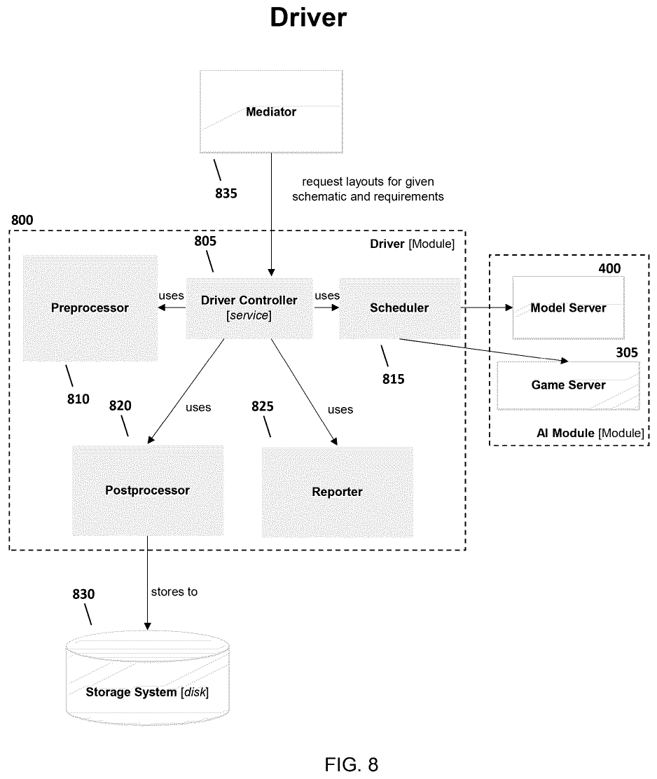

In some cases, the systems, modules, and methods of FIGS. 3A-3D may be managed by a driver 800 as shown in FIG. 8. The driver 800 may comprise a driver controller 805. In some cases, the driver controller 805 comprises the API of the driver 800. In some cases, the driver 800 may communicate with a plurality of sub-modules comprising a preprocessor 810, a scheduler 815, a postprocessor 820, or a reporter 825.

In some cases, the preprocessor 810 may be configured to convert a provided schematic, components, constraints, or targets into a form amenable to the layout game engine 315. In some cases, this process may comprise reducing the submitted problem into an abstracted problem. In some cases, the preprocessor 810 may set up game configurations.

In some cases, the scheduler 815 may be configured to set up a model server 400 or game server 305. In some cases, the game server 305 and model server 400 may form an AI module. In some cases, the scheduler 815 may operate under a computer infrastructure manager framework for managing the model server 400 or game server 305. Generally, the scheduler 815 sets up the servers and schedules their tasks (e.g., training, gameplaying).

In some cases, the reporter 825 may be configured to gather metrics, compute statistics, analyze results, or compile responses. For example, the reporter 825 may manage data to be presented on a GUI. In another example, the reporter 825 may gather training performance such as loss over training epochs. Generally, the reporter 825 may be configured to organize data into a format that may be interpreted by a user.

In some cases, the postprocessor may be configured to reconstruct real solutions from the abstractions. For example, the layout game engine 315 may represent data in a manner amenable to software manipulation and interaction with an AI agent 320, but not amenable to direct export (e.g., as .oa or .gsd files) or presentation to a user. As such, the postprocessor may return states stored in a layout game engine 315 or layout game engine 315 to a format familiar to a user. For example, the postprocessor may output GDSII files. In some cases, the postprocessor may additionally account for some DRC requirements. The postprocessor may be in communication with one or more long-term storage system 830.

In some cases, a driver 800 may be in communication with a mediator. In some cases, the mediator may mediate communications between a user interface and software implementing the systems and methods described herein.

### Digital Layout

In some cases, the quality of a digital circuit may be dependent on layout. In some cases, a digital circuit performance may be limited by layout. This may be particularly true as the demands on speed or performance increase. For example, a serializer/deserializer (SerDes) may be used in the high speed communication of digital signals. In some cases, a SerDes may be limited by their ability to register transitions between 0 and 1 states as clock rates increase. In some cases, the layout of transistors in a SerDes may be adjusted to accommodate increased clock routes. However, a SerDes may have on the order of 100,000 transistors. As such, the process for designing layouts for SerDes transistors may be extremely expensive in terms of computation and labor. Generally, the teachings as applied to analog layouts herein may be used analogously to design digital circuit layouts.

### Computer Systems

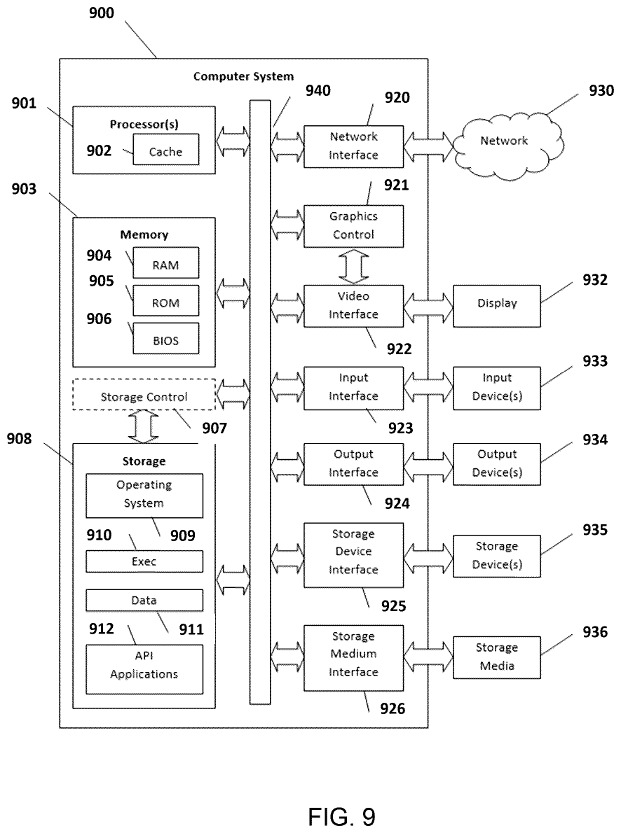

Referring to FIG. 9, a block diagram is shown depicting an illustrative machine that includes a computer system 900 (e.g., a processing or computing system) within which a set of instructions can execute for causing a device to perform or execute any one or more of the aspects and/or methodologies for static code scheduling of the present disclosure. The components in FIG. 9 are examples only and do not limit the scope of use or functionality of any hardware, software, embedded logic component, or a combination of two or more such components implementing particular embodiments. FIG. 9 shows a computer system 900 that is programmed or otherwise configured to implement modules, sub-modules, methods, engines, servers, training, inference, user interfaces, etc., as disclosed herein. The computer system 900 can, for example, train machine learning models of AI agents, receive user constraints/targets/circuit schematics, provide a graphical user interface (GUI) for presentation of layouts and user interaction, evaluate layouts, implement the layout game engine, etc. The computer system 900 can be an electronic device of a user or a computer system that is remotely located with respect to the electronic device. The electronic device can be a mobile electronic device. In some cases, the computer system may implement or communicate with a game server, game manager, layout game engine, AI agent, layout evaluator, driver, or other software module or sub-module as described herein.

Importantly, the computer system 900 may be one of a plurality of computing systems implementing or communicating with each other to execute the systems and methods as described herein. For example, the computer system 900 may comprise a computer of a user accessing locally or remotely served software in communication with a plurality of databases distributed among a plurality of computing systems. To illustrate, cloud storage may be used to maintain user accounts, model checkpoints, or store game replays. In another example, the computer system 900 may facilitate parallel computations among a plurality of computing systems. For example, learning through gameplay or inference operations may be accelerated via one or both of asynchronous or parallel computing on one or more computer systems in communication with computer system 900. In some cases, communications among computer systems may comprise the use of network 930. To illustrate, a platform executing the explore mode as described herein may quickly gather a probability of success in satisfying user targets by executing shallow searches of a plurality of search trees for a user query on a plurality of remote computing systems. The computer system 900 may additionally comprise a plurality of CPUs, GPUs, TPUs, or other processors (e.g., processors 901).

Computer system 900 may include one or more processors 901, a memory 903, and a storage 908 that communicate with each other, and with other components, via a bus 940. The bus 940 may also link a display 932, one or more input devices 933 (which may, for example, include a keypad, a keyboard, a mouse, a stylus, etc.), one or more output devices 934, one or more storage devices 935, and various tangible storage media 936. All of these elements may interface directly or via one or more interfaces or adaptors to the bus 940. For instance, the various tangible storage media 936 can interface with the bus 940 via storage medium interface 926. Computer system 900 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Computer system 900 includes one or more processor(s) 901 (e.g., central processing units (CPUs), general purpose graphics processing units (GPGPUs), or quantum processing units (QPUs)) that carry out functions. Processor(s) 901 optionally contains a cache memory unit 902 for temporary local storage of instructions, data, or computer addresses. Processor(s) 901 are configured to assist in execution of computer readable instructions. Computer system 900 may provide functionality for the components depicted in FIG. 1 as a result of the processor(s) 901 executing non-transitory, processor-executable instructions embodied in one or more tangible computer-readable storage media, such as memory 903, storage 908, storage devices 935, and/or storage medium 936. The computer-readable media may store software that implements particular embodiments, and processor(s) 901 may execute the software. Memory 903 may read the software from one or more other computer-readable media (such as mass storage device(s) 935, 936) or from one or more other sources through a suitable interface, such as network interface 920. The software may cause processor(s) 901 to carry out one or more processes or one or more steps of one or more processes described or illustrated herein. Carrying out such processes or steps may include defining data structures stored in memory 903 and modifying the data structures as directed by the software.

The memory 903 may include various components (e.g., machine readable media) including, but not limited to, a random access memory component (e.g., RAM 904) (e.g., static RAM (SRAM), dynamic RAM (DRAM), ferroelectric random access memory (FRAM), phase-change random access memory (PRAM), etc.), a read-only memory component (e.g., ROM 905), and any combinations thereof. ROM 905 may act to communicate data and instructions unidirectionally to processor(s) 901, and RAM 904 may act to communicate data and instructions bidirectionally with processor(s) 901. ROM 905 and RAM 904 may include any suitable tangible computer-readable media described below. In one example, a basic input/output system 906 (BIOS), including basic routines that help to transfer information between elements within computer system 900, such as during start-up, may be stored in the memory 903.

Fixed storage 908 is connected bidirectionally to processor(s) 901, optionally through storage control unit 907. Fixed storage 908 provides additional data storage capacity and may also include any suitable tangible computer-readable media described herein. Storage 908 may be used to store operating system 909, executable(s) 910, data 911, applications 912 (application programs), and the like. Storage 908 can also include an optical disk drive, a solid-state memory device (e.g., flash-based systems), or a combination of any of the above. Information in storage 908 may, in appropriate cases, be incorporated as virtual memory in memory 903.

In one example, storage device(s) 935 may be removably interfaced with computer system 900 (e.g., via an external port connector (not shown)) via a storage device interface 925. Particularly, storage device(s) 935 and an associated machine-readable medium may provide non-volatile and/or volatile storage of machine-readable instructions, data structures, program modules, and/or other data for the computer system 900. In one example, software may reside, completely or partially, within a machine-readable medium on storage device(s) 935. In another example, software may reside, completely or partially, within processor(s) 901.

Bus 940 connects a wide variety of subsystems. Herein, reference to a bus may encompass one or more digital signal lines serving a common function, where appropriate. Bus 940 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 900 may also include an input device 933. In one example, a user of computer system 900 may enter commands and/or other information into computer system 900 via input device(s) 933. Examples of an input device(s) 933 include, but are not limited to, an alpha-numeric input device (e.g., a keyboard), a pointing device (e.g., a mouse or touchpad), a touchpad, a touch screen, a multi-touch screen, a joystick, a stylus, a gamepad, an audio input device (e.g., a microphone, a voice response system, etc.), an optical scanner, a video or still image capture device (e.g., a camera), and any combinations thereof. In some cases, the input device is a Kinect, Leap Motion, or the like. Input device(s) 933 may be interfaced to bus 940 via any of a variety of input interfaces 923 (e.g., input interface 923) including, but not limited to, serial, parallel, game port, USB, FIREWIRE, THUNDERBOLT, or any combination of the above.

In particular embodiments, when computer system 900 is connected to network 930, computer system 900 may communicate with other devices, specifically mobile devices and enterprise systems, distributed computing systems, cloud storage systems, cloud computing systems, and the like, connected to network 930. Communications to and from computer system 900 may be sent through network interface 920. For example, network interface 920 may receive incoming communications (such as requests or responses from other devices) in the form of one or more packets (such as Internet Protocol (IP) packets) from network 930, and computer system 900 may store the incoming communications in memory 903 for processing. Computer system 900 may similarly store outgoing communications (such as requests or responses to other devices) in the form of one or more packets in memory 903 and communicated to network 930 from network interface 920. Processor(s) 901 may access these communication packets stored in memory 903 for processing.

Examples of the network interface 920 include, but are not limited to, a network interface card, a modem, and any combination thereof. Examples of a network 930 or network segment 930 include, but are not limited to, a distributed computing system, a cloud computing system, a wide area network (WAN) (e.g., the Internet, an enterprise network), a local area network (LAN) (e.g., a network associated with an office, a building, a campus or other relatively small geographic space), a telephone network, a direct connection between two computing devices, a peer-to-peer network, and any combinations thereof. A network, such as network 930, may employ a wired and/or a wireless mode of communication. In general, any network topology may be used.

Information and data can be displayed through a display 932. For example, a .gds, .oa, or other configuration file may be shown on display 932. Examples of a display 932 include, but are not limited to, a liquid crystal display (LCD), a thin film transistor liquid crystal display (TFT-LCD), an organic liquid crystal display (OLED) such as a passive-matrix OLED (PMOLED) or active-matrix OLED (AMOLED) display, a plasma display, and any combinations thereof. The display 932 can interface to the processor(s) 901, memory 903, and fixed storage 908, as well as other devices, such as input device(s) 933, via the bus 940. The display 932 is linked to the bus 940 via a video interface 922, and transport of data between the display 932 and the bus 940 can be controlled via the graphics control 921. In some cases, the display is a video projector. In some cases, the display is a head-mounted display (HMD) such as a VR headset. In further embodiments, suitable VR headsets include, by way of non-limiting examples, HTC Vive, Oculus Rift, Samsung Gear VR, Microsoft HoloLens, Razer OSVR, FOVE VR, Zeiss VR One, Avegant Glyph, Freefly VR headset, and the like. In still further embodiments, the display is a combination of devices such as those disclosed herein.

In addition to a display 932, computer system 900 may include one or more other peripheral output devices 934 including, but not limited to, an audio speaker, a printer, a storage device, and any combinations thereof. Such peripheral output devices may be connected to the bus 940 via an output interface 924. Examples of an output interface 924 include, but are not limited to, a serial port, a parallel connection, a USB port, a FIREWIRE port, a THUNDERBOLT port, and any combinations thereof.

In addition or as an alternative, computer system 900 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a computer-readable medium may encompass a circuit (such as an IC) storing software for execution, a circuit embodying logic for execution, or both, where appropriate. The present disclosure encompasses any suitable combination of hardware, software, or both.

Those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by one or more processor(s), or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In accordance with the description herein, suitable computing devices include, by way of non-limiting examples, cloud computing platforms, distributed computing platforms, server clusters, server computers, desktop computers, laptop computers, notebook computers, sub-notebook computers, netbook computers, netpad computers, handheld computers, Internet appliances, mobile smartphones, and tablet computers.

In some cases, the computing device includes an operating system configured to perform executable instructions. The operating system is, for example, software, including programs and data, which manages the device's hardware and provides services for execution of applications. Those of skill in the art will recognize that suitable server operating systems include, by way of non-limiting examples, FreeBSD, OpenBSD, NetBSD®, Linux, Apple® Mac OS X Server®, Oracle® Solaris®, Windows Server®, and Novell® NetWare®. Those of skill in the art will recognize that suitable personal computer operating systems include, by way of non-limiting examples, Microsoft® Windows®, Apple® Mac OS X®, UNIX®, and UNIX-like operating systems such as GNU/Linux®. In some cases, the operating system is provided by cloud computing. Those of skill in the art will also recognize that suitable mobile smartphone operating systems include, by way of non-limiting examples, Nokia® Symbian® OS, Apple® iOS®, Research In Motion® BlackBerry OS®, Google® Android®, Microsoft® Windows Phone® OS, Microsoft® Windows Mobile® OS, Linux®, and Palm® WebOS®.

### Non-Transitory Computer Readable Storage Medium

In some cases, the platforms, systems, media, and methods disclosed herein include one or more non-transitory computer readable storage media encoded with a program including instructions executable by the operating system of an optionally networked computing device. In further embodiments, a computer readable storage medium is a tangible component of a computing device. In still further embodiments, a computer readable storage medium is optionally removable from a computing device. In some cases, a computer readable storage medium includes, by way of non-limiting examples, CD-ROMs, DVDs, flash memory devices, solid state memory, magnetic disk drives, magnetic tape drives, optical disk drives, distributed computing systems including cloud computing systems and services, and the like. In some cases, the program and instructions are permanently, substantially permanently, semi-permanently, or non-transitorily encoded on the media.

### Computer Program

In some cases, the platforms, systems, media, and methods disclosed herein include at least one computer program, or use of the same. A computer program includes a sequence of instructions, executable by one or more processor(s) of the computing device's CPU, written to perform a specified task. Computer readable instructions may be implemented as program modules, such as functions, objects, Application Programming Interfaces (APIs), computing data structures, and the like, that perform particular tasks or implement particular abstract data types. In light of the disclosure provided herein, those of skill in the art will recognize that a computer program may be written in various versions of various languages.

The functionality of the computer readable instructions may be combined or distributed as desired in various environments. In some cases, a computer program comprises one sequence of instructions. In some cases, a computer program comprises a plurality of sequences of instructions. In some cases, a computer program is provided from one location. In other embodiments, a computer program is provided from a plurality of locations. In various embodiments, a computer program includes one or more software modules. In various embodiments, a computer program includes, in part or in whole, one or more web applications, one or more mobile applications, one or more standalone applications, one or more web browser plug-ins, extensions, add-ins, or add-ons, or combinations thereof.

### Web Application

In some cases, a computer program includes a web application. In light of the disclosure provided herein, those of skill in the art will recognize that a web application, in various embodiments, utilizes one or more software frameworks and one or more database systems. In some cases, a web application is created upon a software framework such as Microsoft® .NET or Ruby on Rails (RoR). In some cases, a web application utilizes one or more database systems including, by way of non-limiting examples, relational, non-relational, object oriented, associative, XML, and document oriented database systems. In further embodiments, suitable relational database systems include, by way of non-limiting examples, Microsoft® SQL Server, mySQL™, and Oracle®. Those of skill in the art will also recognize that a web application, in various embodiments, is written in one or more versions of one or more languages. A web application may be written in one or more markup languages, presentation definition languages, client-side scripting languages, server-side coding languages, database query languages, or combinations thereof. In some cases, a web application is written to some extent in a markup language such as Hypertext Markup Language (HTML), Extensible Hypertext Markup Language (XHTML), or extensible Markup Language (XML). In some cases, a web application is written to some extent in a presentation definition language such as Cascading Style Sheets (CSS). In some cases, a web application is written to some extent in a client-side scripting language such as Asynchronous Javascript and XML (AJAX), Flash® ActionScript, JavaScript, or Silverlight®. In some cases, a web application is written to some extent in a server-side coding language such as Active Server Pages (ASP), ColdFusion®, Perl, Java™, JavaServer Pages (JSP), Hypertext Preprocessor (PHP), Python™, Ruby, Tcl, Smalltalk, WebDNA®, or Groovy. In some cases, a web application is written to some extent in a database query language such as Structured Query Language (SQL). In some cases, a web application integrates enterprise server products such as IBM® Lotus Domino®. In some cases, a web application includes a media player element. In various further embodiments, a media player element utilizes one or more of many suitable multimedia technologies including, by way of non-limiting examples, Adobe® Flash®, HTML 5, Apple® QuickTime®, Microsoft® Silverlight®, Java™, and Unity®.

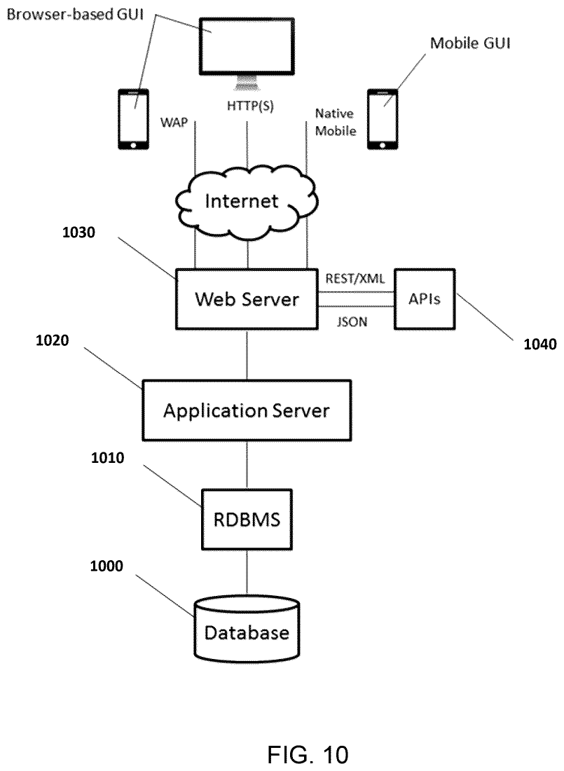

Referring to FIG. 10, in a particular embodiment, an application provision system comprises one or more databases 1000 accessed by a relational database management system (RDBMS) 1010. Suitable RDBMSs include Firebird, MySQL, PostgreSQL, SQLite, Oracle Database, Microsoft SQL Server, IBM DB2, IBM Informix, SAP Sybase, Teradata, and the like. In this embodiment, the application provision system further comprises one or more application servers 1020 (such as Java servers, .NET servers, PHP servers, and the like) and one or more web servers 1030 (such as Apache, IIS, GWS and the like). The web server(s) optionally expose one or more web services via app application programming interfaces (APIs) 1040. Via a network, such as the Internet, the system provides browser-based and/or mobile native user interfaces.

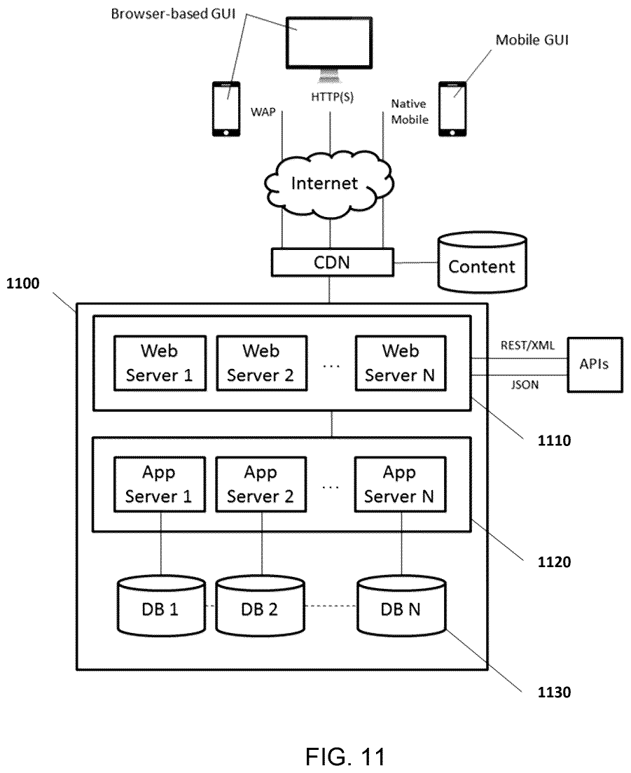

Referring to FIG. 11, in a particular embodiment, an application provision system alternatively has a distributed, cloud-based architecture 1100 and comprises elastically load balanced, auto-scaling web server resources 1110 and application server resources 1120 as well synchronously replicated databases 1130.

### Mobile Application

In some cases, a computer program includes a mobile application provided to a mobile computing device. In some cases, the mobile application is provided to a mobile computing device at the time it is manufactured. In other embodiments, the mobile application is provided to a mobile computing device via the computer network described herein.

In view of the disclosure provided herein, a mobile application is created by techniques known to those of skill in the art using hardware, languages, and development environments known to the art. Those of skill in the art will recognize that mobile applications are written in several languages. Suitable programming languages include, by way of non-limiting examples, C, C++, C #, Objective-C, Java™, JavaScript, Pascal, Object Pascal, Python™, Ruby, VB.NET, WML, and XHTML/HTML with or without CSS, or combinations thereof.

Suitable mobile application development environments are available from several sources. Commercially available development environments include, by way of non-limiting examples, AirplaySDK, alcheMo, Appcelerator®, Celsius, Bedrock, Flash Lite, .NET Compact Framework, Rhomobile, and WorkLight Mobile Platform. Other development environments are available without cost including, by way of non-limiting examples, Lazarus, MobiFlex, MoSync, and PhoneGap. Also, mobile device manufacturers distribute software developer kits including, by way of non-limiting examples, iPhone and iPad (iOS) SDK, Android™ SDK, BlackBerry® SDK, BREW SDK, Palm® OS SDK, Symbian SDK, webOS SDK, and Windows® Mobile SDK.

### Standalone Application

In some cases, a computer program includes a standalone application, which is a program that is run as an independent computer process, not an add-on to an existing process, e.g., not a plug-in. Those of skill in the art will recognize that standalone applications are often compiled. A compiler is a computer program(s) that transforms source code written in a programming language into binary object code such as assembly language or machine code. Suitable compiled programming languages include, by way of non-limiting examples, C, C++, Objective-C, COBOL, Delphi, Eiffel, Java™, Lisp, Python™, Visual Basic, and VB .NET, or combinations thereof. Compilation is often performed, at least in part, to create an executable program. In some cases, a computer program includes one or more executable compiled applications.

### Software Modules

In some cases, the platforms, systems, media, and methods disclosed herein include software, server, and/or database modules, or use of the same. In view of the disclosure provided herein, software modules are created by techniques known to those of skill in the art using machines, software, and languages known to the art. The software modules disclosed herein are implemented in a multitude of ways. In various embodiments, a software module comprises a file, a section of code, a programming object, a programming structure, a distributed computing resource, a cloud computing resource, or combinations thereof. In further various embodiments, a software module comprises a plurality of files, a plurality of sections of code, a plurality of programming objects, a plurality of programming structures, a plurality of distributed computing resources, a plurality of cloud computing resources, or combinations thereof. In various embodiments, the one or more software modules comprise, by way of non-limiting examples, a web application, a mobile application, a standalone application, and a distributed or cloud computing application. In some cases, software modules are in one computer program or application. In other embodiments, software modules are in more than one computer program or application. In some cases, software modules are hosted on one machine. In other embodiments, software modules are hosted on more than one machine. In further embodiments, software modules are hosted on a distributed computing platform such as a cloud computing platform. In some cases, software modules are hosted on one or more machines in one location. In other embodiments, software modules are hosted on one or more machines in more than one location.

### Databases

In some cases, the platforms, systems, media, and methods disclosed herein include one or more databases, or use of the same. In view of the disclosure provided herein, those of skill in the art will recognize that many databases are suitable for storage and retrieval of model parameters, training data, or user account information. In various embodiments, suitable databases include, by way of non-limiting examples, relational databases, non-relational databases, object oriented databases, object databases, entity-relationship model databases, associative databases, XML databases, document oriented databases, and graph databases. Further non-limiting examples include SQL, PostgreSQL, MySQL, Oracle, DB2, Sybase, and MongoDB. In some cases, a database is Internet-based. In further embodiments, a database is web-based. In still further embodiments, a database is cloud computing-based. In a particular embodiment, a database is a distributed database. In other embodiments, a database is based on one or more local computer storage devices.

### Machine Learning

As used in this specification and the appended claims, the terms “machine learning” (ML) or “artificial intelligence” may refer to a system or model that may learn via training operations to progressively improve computer performance of a task.

A machine learning model herein may comprise neural networks and classical machine learning algorithms. A neural network may comprise a perceptron, a convolutional neural network, a recurrent neural network, a long-short-term memory network, a transformer, a residual neural network, or any machine learning model comprising layers of neurons, convolutional filters, the self-attention mechanism, or other architectural component of the listed neural networks. A classical machine learning algorithm may comprise a clustering algorithm, a decision tree-based algorithm, a polynomial regression algorithm, a gaussian regression algorithm, a support vector machine algorithm, a logistic regression algorithm, or other non-neural network based machine learning algorithm.

Training the ML model may include, in some cases, selecting one or more untrained data models to train using a training data set. The selected untrained data models may include any type of untrained ML models for supervised, semi-supervised, self-supervised, or unsupervised machine learning. The selected untrained data models may be specified based upon input (e.g., user input) specifying relevant parameters to use as predicted variables or other variables to use as potential explanatory variables. For example, the selected untrained data models may be specified to generate an output (e.g., a prediction) based upon the input. Conditions for training the ML model from the selected untrained data models may likewise be selected, such as limits on the ML model complexity (e.g., hyperparameter selection) or limits on the ML model refinement past a certain point (e.g., regularization). The ML model may be trained (e.g., via a computer system such computer system 901) using a training data set. In some cases, a first subset of the training data set may be selected to train the ML model. The selected untrained data models may then be trained on the first subset of training data set using appropriate ML techniques, based upon the type of ML model selected and any conditions specified for training the ML model. In some cases, due to the processing power requirements of training the ML model, the selected untrained data models may be trained using additional computing resources (e.g., cloud computing resources). Such training may continue, in some cases, until at least one aspect of the ML model is validated and meets selection criteria to be used as a predictive model.

In some cases, one or more aspects of the ML model may be validated using a second subset of the training data set (e.g., distinct from the first subset of the training data set) to determine accuracy and robustness of the ML model. Such validation may include applying the ML model to the second subset of the training data set to make predictions derived from the second subset of the training data. The ML model may then be evaluated to determine whether performance is sufficient based upon the derived predictions. The sufficiency criteria applied to the ML model may vary depending upon the size of the training data set available for training, the performance of previous iterations of trained models, or user-specified performance requirements. If the ML model does not achieve sufficient performance, additional training may be performed. Additional training may include refinement of the ML model or retraining on a different first subset of the training dataset, after which the new ML model may again be validated and assessed. When the ML model has achieved sufficient performance, in some cases, the ML may be stored for present or future use. The ML model may be stored as sets of parameter values or weights for analysis of further input (e.g., further relevant parameters to use as further predicted variables, further explanatory variables, further user interaction data, etc.), which may also include analysis logic or indications of model validity in some instances. In some cases, a plurality of ML models may be stored for generating predictions under different sets of input data conditions. In some cases, the ML model may be stored in a database (e.g., associated with a server).

### Definitions

Unless defined otherwise, all terms of art, notations and other technical and scientific terms or terminology used herein are intended to have the same meaning as is commonly understood by one of ordinary skill in the art to which the claimed subject matter pertains. In some cases, terms with commonly understood meanings are defined herein for clarity or for ready reference, and the inclusion of such definitions herein should not necessarily be construed to represent a substantial difference over what is generally understood in the art.

As used herein, the singular forms “a,” “an,” and “the” include plural references unless the context clearly dictates otherwise. For example, the term “a sample” includes a plurality of samples, including mixtures thereof. The use of alternative (e.g., “or”) should be understood to mean either one, both, or any combination thereof of the alternatives. As used herein, the terms “include” and “comprise” are used synonymously.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

Certain inventive embodiments herein contemplate numerical ranges. When ranges are present, the ranges include the range endpoints. Additionally, every sub range and value within the range is present as if explicitly written out.

The term “about,” “substantially,” or “approximately” may mean within an acceptable error range for the particular value, which will depend in part on how the value is measured or determined, e.g., the limitations of the measurement system. For example, “about” may mean within 1 or more than 1 standard deviation, per the practice in the art. Alternatively, “about” may mean a range of up to 20%, up to 10%, up to 5%, or up to 1% of a given value. Where particular values are described in the application and claims, unless otherwise stated the term “about” meaning within an acceptable error range for the particular value may be assumed.

A “layout” as described herein may be used to denote the organization of circuit components and their inter-connections. A layout may be a graph representation of circuit components. In some cases, this graph representation may be a circuit schematic. These graph representations, or circuit schematics, may comprise idealized representations of circuits that do not account for real-world limitations of performance based on physical organization of components. Accordingly, the layout may comprise the physical organization of properly scaled and connected circuit components that may be evaluated for real world performance and ultimately used to fabricate analog circuits.

A “game engine” as described herein may be used to denote the representation of a problem including its layout and constraints or rules. Generally, the game engine herein may be used to provide a current state or past state of an analog layout during the design process, one or more trackers to track components or wires remaining to be placed, an evaluator for evaluating layouts for adherence to constraints or for presenting with a desired performance, and the ability to update states given an action. In some cases, the game engine may be able to import an action and export an updated state of an analog layout. In some cases, the state may be represented or converted via data transformation techniques to render the states amenable to machine learning models. For example, the game engine may output a state as an array, matrix, or tensor for use as input into a machine learning model.

A “game” as described herein may be used to denote the generation of an analog layout based on a set of constraints and targets. For example, an AI agent may play the layout game by choosing actions with high expected score, those actions including placing, sizing, organizing, routing, etc. circuit components on a grid to arrive at an analog layout design. To illustrate, an AI agent may decide to place a transistor on a grid at a particular location due in part to an expected score for that placement (e.g., a good analog layout). Generally, this can be analogized to chess. For example, in moving a chess piece, the expected value of that move in leading to a win for the player may be determined by a machine learning model of an AI agent configured to play chess. As such, the AI agent may advance the game of chess by outputting the action necessary to move the chess piece to the position with a high estimated score.

An “artificial intelligence agent” or “AI agent” as described herein may comprise software executed by one or more processors on one or more computers to play the game of analog layout design. An AI agent may comprise one or more machine learning models. An AI agent may interact with a layout game engine and make decisions on how to modify a state of an analog circuit represented in that layout game engine to achieve a goal. For example, the AI agent may take as input a current state of an incomplete analog layout design and determine one or more likely desirable actions to achieve a layout design with desired properties (or targets). Generally, the AI agent may be analogized to a player of a game.

A “policy network” or “policy model” as described herein may be used to denote a machine learning model used to predict a probability of an action given a state. For example, there may be a large number of possible actions an AI agent may output for a given state of an analog layout. As such, the policy network may be used to guide the AI agent to output an action by providing a probability that an action ought to be taken from a given state. For example, a policy network may learn through training on data of past states and actions which actions are most likely to result in a high score from a given state. The policy network may be said to learn a policy for outputting an action given a state.

A “value network” or “value model” as described herein may be used to denote a machine learning model used to predict an expected final score for a completion of a partial layout. For example, an AI agent may select an action based in part on an expected final score of a state resulting from the action. In layout design, for example, a component may be added to a circuit grid based on an expected final score that the placement may provide. Herein, the value network may be trained based on differences between a predicted score for a given state and the scores of layouts ultimately derived from that given state.

An “action” or “move” as described herein may be used to denote a decision made by an AI agent relating to the action taken to update the state of an analog layout. For example, a transistor may be placed in a plurality of locations on a circuit grid. Accordingly, the operation or move of the AI agent may be to select one or more placements for the transistor. In some cases, an action used to update a state may be output by an AI agent as a result of a Monte Carlo Tree Search.

A “target” as described herein may be used to denote desired behaviors or organizations of an analog circuit as indicated by a user or as automatically selected during training of an AI agent. For example, a target of an AI agent may comprise a performance of the ultimately generated circuit with a given layout. To illustrate, a user may desire a parasitic resistance between two pins of a transistor to fall below a threshold. As such, the AI agent responsible for providing layouts may be scored for providing or searching layout paths that satisfy or nearly satisfy the threshold for parasitic resistance. In some cases, a target may not be satisfied by a layout provided by an AI agent. Generally, a target may serve to guide analog layout design via the penalization or score of certain actions of the AI agent but may not be fully satisfied by the AI agent.

A “constraint” as described herein may be used to denote limits on the possible actions or moves proposed by the AI agent during the generation of a layout. In other words, an AI agent is unable to modify a constraint when generating a layout. For example, a constraint may exclude an otherwise legal action for updating a state. To illustrate, a policy network may predict a certain move as highly likely based on a given state of a layout. However, the output of the policy network may be over-ridden either by a flag in the input or via post-processing to prevent the AI agent from exploring constrained options. To illustrate, a user may constrain a circuit grid to a 16×16 grid of blocks. As such, potential operations that would violate the width of the circuit grid would be excluded based on a constraint. In some cases, the constraint may be provided by a user or by software configured to train machine learning models of the AI agent through gameplay. In some cases, a circuit schematic may be considered a constraint. For example, the AI agent may be constrained from updating the state in a manner inconsistent with the circuit schematic (e.g., AI agent will not propose adding a 5^{th} transistor to a 4 transistor circuit). In some cases, a constraint may be a design rule of a design rule check (DRC). In some cases, a circuit schematic may be an output from an electronic design automation (EDA) software.

A “state” as described herein may be used to denote a current condition of a layout of analog components and the inter-connection among components. For example, an analog layout may be partially completed by having three of four transistors placed and routed. This condition may be a state of the layout. The state may be a subject of an action of an AI agent. For example, the AI agent may be configured to take the current state as input and propose a next action to update the state. The iterative process of taking in states and suggesting actions by the AI agent may result in a realized analog layout design. Generally, the layout game engine comprises the state, the rules for updating the state, a mechanism to update the state given an action, and the processing operations to send the state to the AI agent and receive actions from the AI agent.

A “component” as described herein may comprise elements of a circuit such as transistors, resistors, capacitors, thermistors, inductors, diodes, or other elements that augment, mitigate, amplify, switch, change, route, or alter signals passing through or generated by an analog circuit. In some cases, a component may be a combination of elements of a circuit. For example, a component may comprise a differential pair, which comprises a pair of transistors. In some cases, a wire may be considered a component. In some cases, a component can be an active (e.g., transistors, op-amps) or a passive (e.g., resistors, capacitors) component.

A “score” as described herein may be used to denote a representation of quality of an analog circuit. The score may be used to train one or more machine learning model of the AI agent. For example, an AI agent may determine a plurality of layouts for a given iteration of layout generation. Accordingly, each of the plurality of layouts may be evaluated to determine a score that can be used to train a machine learning model to predict scores from states (e.g., value network) or to actions for a given state (e.g., policy network). In some cases, a score may be based upon factors including adherence to targets, design rule checks, layout-versus-schematic evaluations, parasitic extraction checks, physics or mathematical solvers or approximations thereof, simulations, or output signal ideality.

A “net” as described herein may be used to denote a collection of wires that are electrically connected. For example, a circuit schematic as described herein may comprise a plurality of transistors connected to external components (e.g., power supplies) or other internal components (e.g., other transistors). As such, the nets as described herein may comprise representations of the connection points of wires used to connect the electrical components among internal and external components of a circuit. In some cases, a net may be one or more metal wire, one or more via, or combinations thereof.

“Reinforcement learning” herein may be used to denote AI systems that use trial and error and delayed scores to learn to make decisions. Herein, reinforcement learning may leverage self-learning through gameplay. In some cases, reinforcement learning may comprise the training of one or more machine learning model of an AI agent interacting with a layout game engine. For example, reinforcement learning herein may be used to train AI agents for analog layout design.

### EXAMPLES

The following examples are included for illustrative purposes only and are not intended to limit the scope of the inventive concepts.

### Example 1: Illustrative Training Mode of a Self-Play/Game Playing System

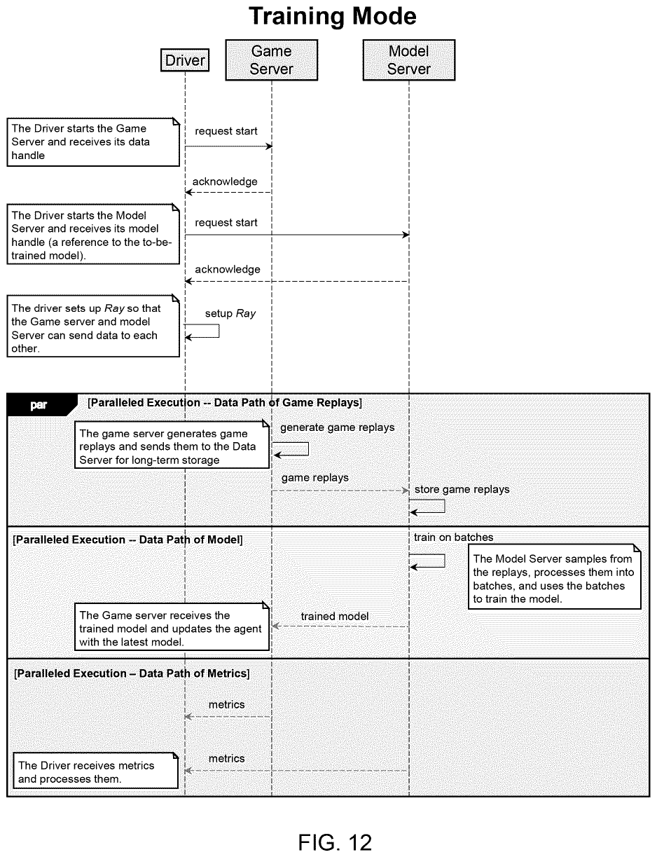

Shown in FIG. 12 is an illustrative training mode implemented by software modules and servers as described herein. In this training mode, the driver receives a data handle comprising a reference to the to-be-generated game replays and a model handle comprising a reference to the to-be-trained model. The driver also sets up Ray to facilitate data and model sharing between the game and model servers. Generally, Ray is a software framework used to manage, execute, and optimize AI computing needs.

Following initialization, driver executes, in parallel (“par”), a plurality of operations. In one thread or subset of threads, the game server generates replays and stores them via a data server. At least a portion of the data replays are sent to the model server for storage as well. The synthetic data described elsewhere herein may comprise the game replays. The model server is configured to train a machine learning model of the AI agent on batches of the game replays. Upon training, the trained model is sent back to the game server, which updates the AI model with the updated machine learning model or models. Additionally, training metrics (e.g., describing loss/performance of the models) and metrics of the generated layouts (e.g., from layout evaluation) are communicated to the driver. These metrics may be processed for evaluation by a user or stored.

### Example 2: Illustrative Inference Mode of a Self-Play/Game Playing System

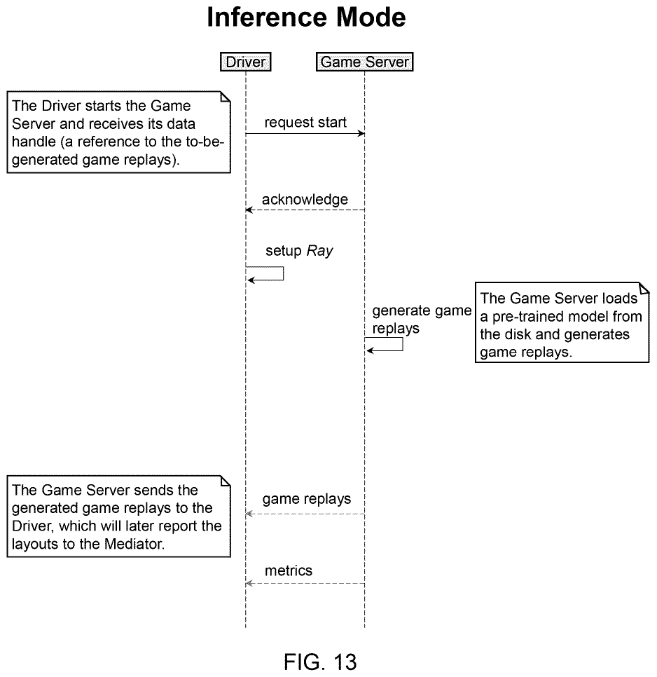

Shown in FIG. 13 is an illustrative inference mode implemented by software modules and servers as described herein. In this inference mode, the driver starts the game server and receives its data handle comprising a reference to the to-be-generated game replays. The driver also initializes Ray to facilitate management and execution of the inference tasks. The game server loads the machine learning model(s) into an AI agent and generates game replays.

The game replays and metrics of the generated layouts are returned to the driver. The driver may optionally report the layouts and the metrics to a mediator. The mediator may present the layouts and the metrics to a user.

### Example 3: Illustrative Interfaces Exposed to User During Inference

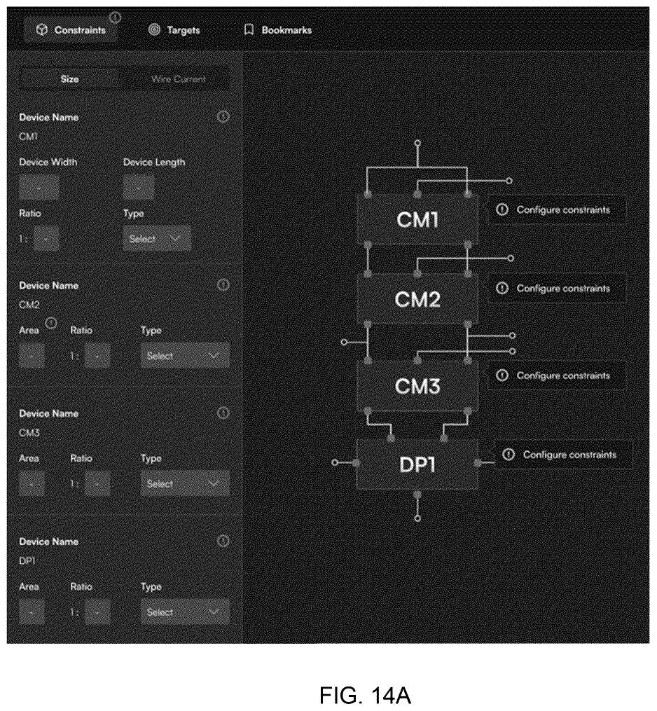

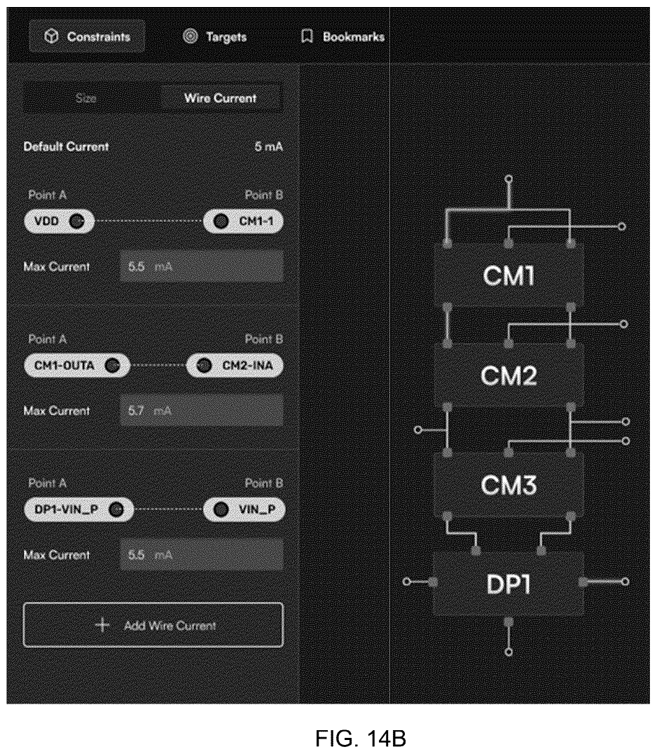

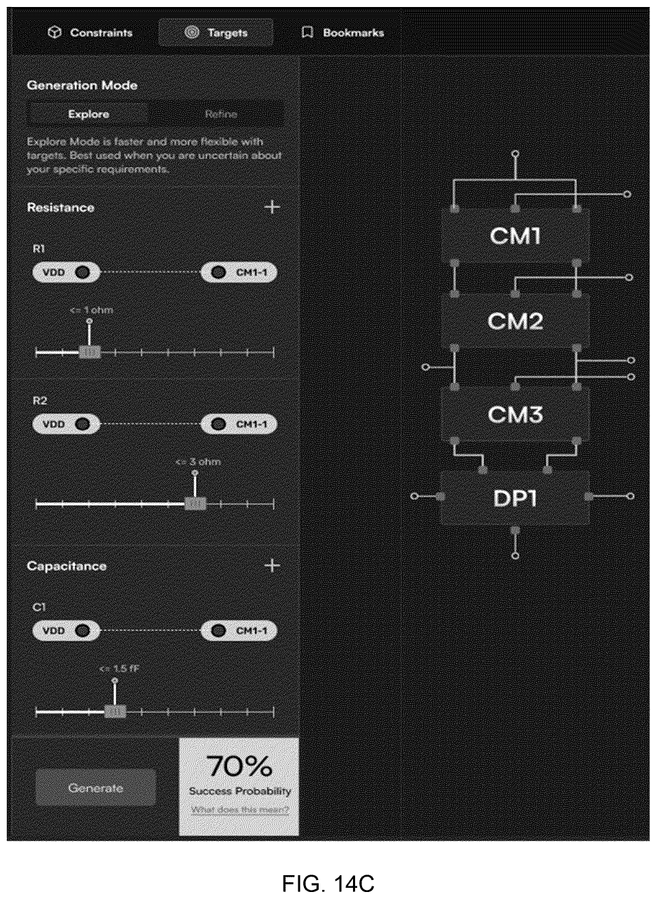

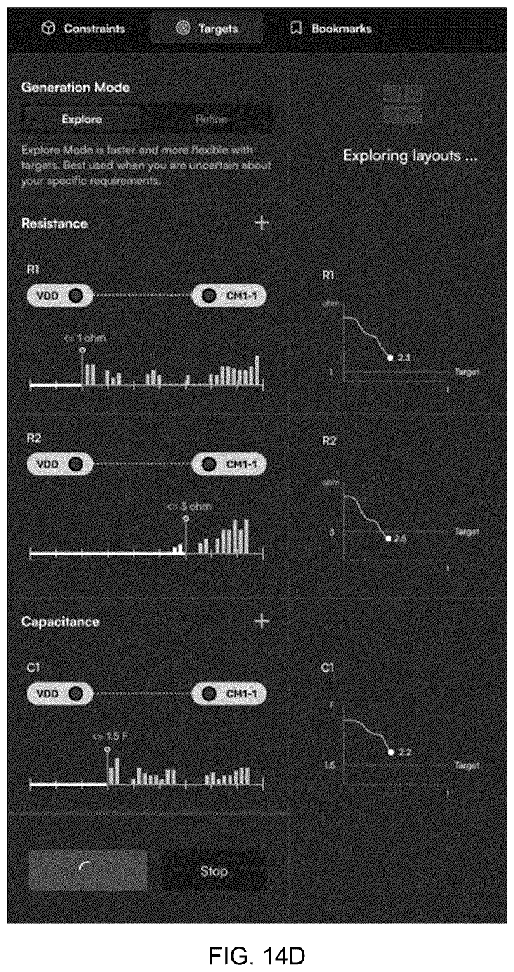

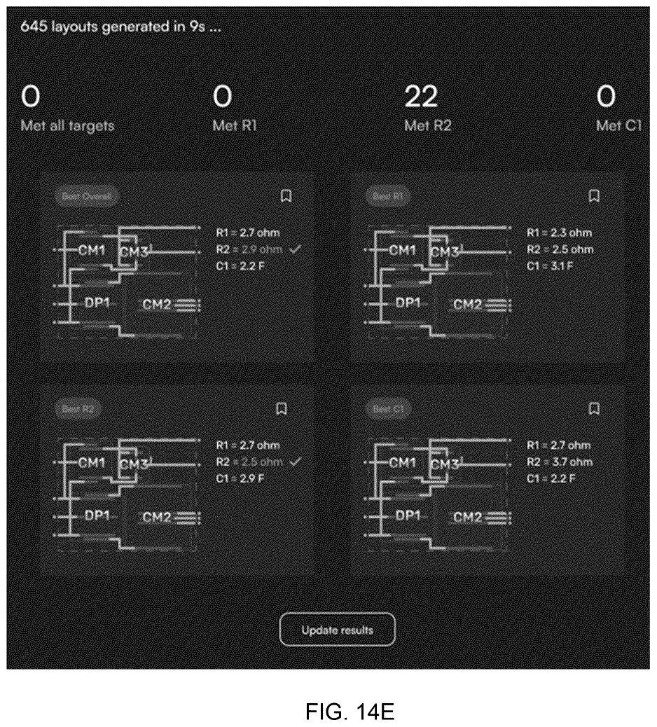

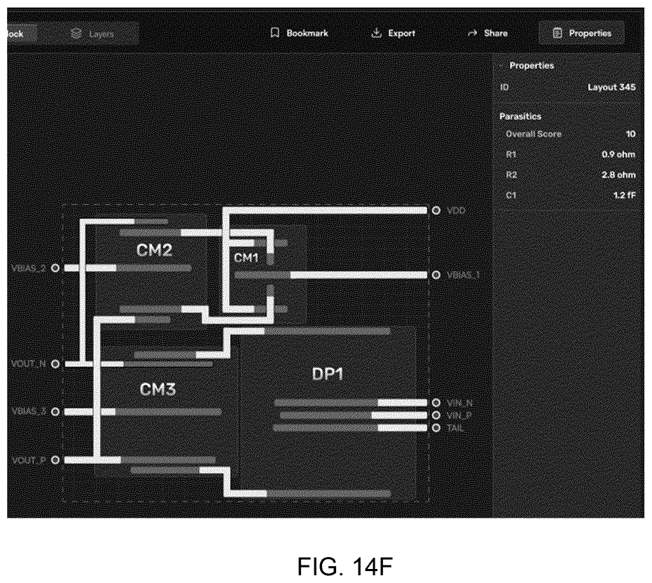

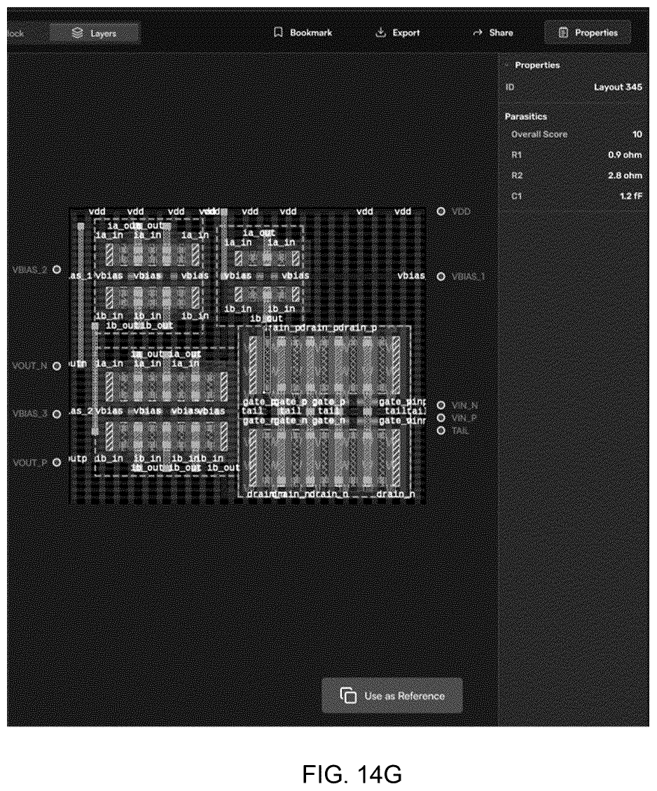

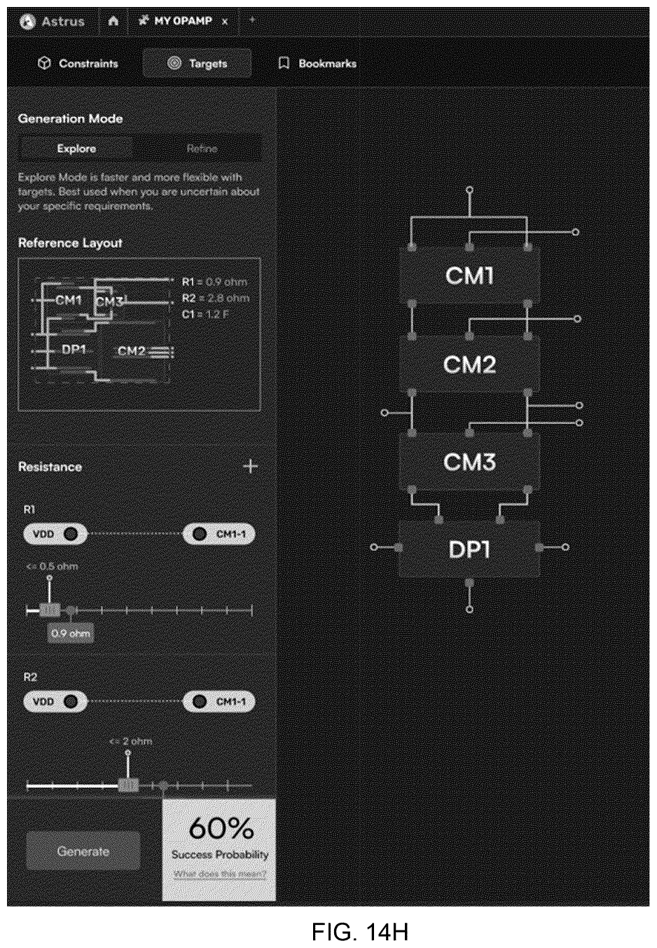

Shown in FIG. 14A is an illustrative GUI exposed to a user. On the left are a plurality of configurable size constraints presented to a user. On the right is a labeled circuit schematic showing four components and a plurality of nets. The circuit schematic is not a representation of the final layout of the realized analog circuit. As shown the user can configure constraints such as widths, lengths, width to height ratios, and types of components. Shown in FIG. 14B is the same circuit schematic, but with wire current constraints presented to the user for configuration. For example, the VDD (external power source) to component CM1-1 (current mirror 1) max wire current is set at 5.5 mA.

Shown in FIG. 14C are the configurable targets of the circuit schematic for the user desired layout(s). In FIG. 14C, the user has selected explore mode. The explore mode is a dynamic, fast, shallow search of the possible layouts that the AI agent performs to gauge the likelihood that give combination of targets will be satisfied. For example, as shown the user desires a resistance between the VDD and pin 1 of CM1-1 of less than or equal to 1Ω, a resistance between the VDD and pin 2 of CM1-1 of less than or equal to 3Ω, and a capacitance between VDD and pin 1 of CM1-1 of less than or equal to 1.5 fF. As shown, the AI agent expects a 70% probability of success in finding a layout of analog components that will satisfy the users targets. The probability of success is output by a success probability network based on the user provided targets.

Shown in FIG. 14D is the left side still shot of a GUI during inference gameplay. As shown on the left, the user is provided a plurality of histograms and convergence plots showing the realized behavior of the various generated layouts, in this case 645 layouts after about 9 seconds. These histograms and plots provide a visual indication of the distribution in realized behavior of analog circuits versus their targets. These histograms may be filtered by the user to show the overlap among various performance metrics determined for the layouts. Additionally, as shown on the right side of the still shot of the GUI in FIG. 14E, various layouts are presented to the user and ordered according to a measure of their quality (e.g., number of targets met). Users can bookmark these layouts for later review or refinement.

Shown in FIG. 14F is a layout satisfying each of the user targets. The layout comprises a resistance between the VDD and pin 1 of CM1-1 of 0.9Ω, a resistance between the VDD and pin 2 of CM1-1 of 2.8Ω, and a capacitance between VDD and pin 1 of CM1-1 of 1.2 fF. FIG. 14G shows the same layout in GDSII format. Further, as shown, the user is presented with the option to mark the layout as a reference.

The use of the layout of FIG. 14G, marked as a reference layout by user, is shown in a second iteration of explore mode as shown in FIG. 14H. The reference layout provides the user with a baseline of target values which they know by demonstration is achievable along with the associated layout. The user can use a reference layout to set reasonable initial values for targets which they can then further refine, for example by providing more stringent targets. In this case, the AI agent predicts a 60% probability that a layout satisfying a resistance between the VDD and pin 1 of CM1-1 of less than or equal to 0.5Ω is achievable. The probability of success is output by a success probability network based on the user provided targets.

### Example 4: Illustrative Ideal Vs. Realized Waveform

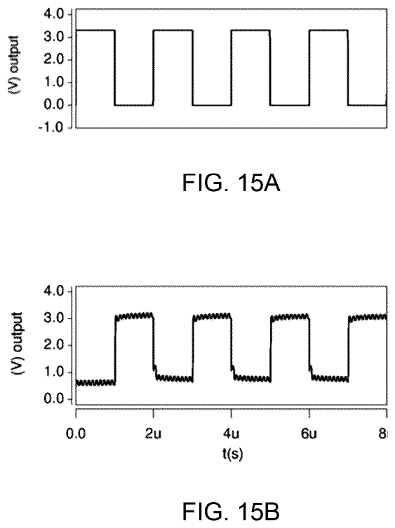

FIG. 15A shows an ideal, or target, waveform of an analog circuit. FIG. 15B shows a waveform output of a realized analog circuit. A score is calculated based on the difference between the waveform shown in FIG. 15A and FIG. 15B and is used to train a machine learning model of an AI agent.

### Example 5: Illustrative Layout Design Between Analog Designer and Layout Engineer

To illustrate the existing process of generating layouts, the following simple scenario is provided. An analog designer desires a realization of their circuit schematic describing an inverter with two transistors. An inverter flips bits in a computer. The analog designer provides a schematic comprising transistors and their connections to each other, power, input, output, and ground. The analog designer tweaks their schematic until a simulated behavior of the circuit is achieved. The circuit schematic is then provided to a layout engineer. In addition to the schematic, the designer conveys additional requirements (or targets).

The layout engineer uses the targets and the circuit schematic to build a candidate layout of a realized analog circuit. The layout comprises the transistors and connections provided by the analog designer. The first layout fails a design rule check (DRC). The DRC dictates that the layout has wires that are too close together. This necessitates a first update to the layout, thereby resulting in a second layout. The second layout passes the DRC by rerouting the wires so as to be further apart.

The layout engineer passes the second layout to the analog designer who runs a parasitic extraction simulation. The analog designer determines that there will be a large resistance along one of the wires connecting the transistors. A simulation of the output form of the circuit comprising the layout confirms a substantial lack of ideality, a lack proposed by the analog designer as resulting from the large resistance along the aforementioned wire. The analog designer decreases that resistance in their simulation and determines that the analog circuit would have the desired behavior if that resistance could be decreased to less than 2Ω from the current value of 12Ω.

The analog designer passes this updated information to the layout engineer. The layout engineer predicts that moving the transistors closer to the output portion of the grid on which they were placed would decrease this resistance. This third layout passes DRC and is then handed back to the analog designer.

The analog designer simulates the output waveform of the analog circuit comprising the third layout and is satisfied. The analog circuit is fabricated.

1. A method for optimizing a layout of an electronic circuit according to a parasitic capacitance, a parasitic resistance, or a matched wire percent time constant difference comprising:
(a) receiving an electronic circuit schematic and one or more target of the electronic circuit, wherein the electronic circuit schematic comprises a plurality of circuit components including at least one analog circuit component, and wherein the one or more target comprises the parasitic capacitance, the parasitic resistance, or the matched wire percent time constant difference;
(b) selecting an action of a plurality of actions to update the layout of the electronic circuit with an artificial intelligence (AI) agent, wherein the plurality of actions comprise:
(i) determining a size of a circuit component of the plurality of circuit components,
(ii) determining a placement of the circuit component of the plurality of circuit components, and
(iii) determining a routing of a portion of the electronic circuit; and
(c) automatically optimizing the layout of the electronic circuit based on the action selected by the AI agent, wherein the AI agent is trained to select between at least two actions of the plurality of actions based on the one or more target, and wherein a target of the one or more target describes a desired performance of the electronic circuit.

2. The method of claim 1, wherein the AI agent is trained from scratch with no pre-existing training dataset.

3. The method of claim 1, wherein the AI agent is trained solely via gameplay, wherein gameplay is used to iteratively generate a plurality of training datasets for training the AI agent.

4. The method of claim 3, wherein a training dataset of the plurality of training datasets comprises a game replay, wherein a game replay comprises a state of the layout of the electronic circuit, an action selected to update the state of the layout of the electronic circuit, and a score for the selected action.

5. The method of claim 21, wherein the lookahead search comprises operations including:
i. selecting a training action of the plurality of actions,
ii. determining a score for the training action of the plurality of actions based on one or more training target,
iii. generating a game replay comprising the action of the plurality of actions and the score, wherein a training dataset comprises the game replay, and
iv. training the AI agent on the training dataset to optimize the score when selecting the action of the plurality of actions.

6. (canceled)

7. The method of claim 1, wherein the one or more target is used to determine a score for the action of the plurality of actions, wherein the score comprises a calculation of the performance of the electronic circuit comprising the layout resultant from the action selected in (b).

8. The method of claim 7, wherein the calculation of the performance comprises a comparison with an output of a post-layout extraction check (PEX), a simulation of an electronic circuit waveform, or a physics solver.

9. The method of claim 8, wherein the score is further based on a design rule check (DRC) or a layout-versus-schematic check (LVS).

10. The method of claim 1, wherein the action of the plurality of actions is selected to optimize the layout according to the one or more target.

11. The method of claim 1, further comprising outputting a computer file configured to guide a fabrication of the electronic circuit.

12. The method of claim 1, further comprising:
(d) generating an evaluation of the layout of the electronic circuit to determine a performance of the electronic circuit comprising the layout versus the desired performance of the electronic circuit;
(e) providing the layout and the evaluation to a user to receive an updated target; and
(f) performing (a)-(e) until the user approves the layout of the electronic circuit.

13. The method of claim 1, further comprising fabricating the electronic circuit.

14. The method of claim 1, wherein (b) is performed until each circuit component of the plurality of circuit components is used to update the layout of the electronic circuit.

15. The method of claim 1, wherein the AI agent performs a lookahead search in (b) to select the action of the plurality of actions.

16. The method of claim 15, wherein the lookahead search is based on an output of a machine learning model.

17. The method of claim 1, further comprising displaying the layout of the electronic circuit on a graphical user interface.

18. The method of claim 1, further comprising displaying a distribution of a plurality of layouts generated by (a)-(c), wherein the distribution shows a performance of each layout of the plurality of layouts versus a target of the one or more target.

19. The method of claim 1, further comprising displaying a success probability to a user based on the one or more target.

20. The method of claim 19, wherein the success probability is output by a success probability network.

21. The method of claim 1, wherein the AI agent is iteratively trained using a lookahead search.
